(19) United States
(12) Patent Application Publication
(10) Pub. No.: US 2011/0022929 A1
(43) Pub. Date: Jan. 27, 2011

(54) Error correcting apparatus, method of controlling memory of error correcting apparatus, and optical disc recording/reproducing apparatus

(75) Inventor: Kazuhiko Yamada, Kanagawa (JP)

Correspondence Address: RADER FISHMAN & GRAUER PLLC, LION BUILDING, 1233 20TH STREET N.W., SUITE 501, WASHINGTON, DC, 20036, US

(73) Assignee: Sony Corporation, Tokyo (JP)

(21) Appl. No.: 12/801,996

(22) Filed: Jul. 7, 2010

(30) Foreign Application Priority Data
Jul. 22, 2009 (JP) 2009-171467

(51) Int. Cl. H03M 13/05; G06F 11/10

(52) U.S. Cl. 714/763; 714/E11.034

(57) ABSTRACT

An error correcting apparatus includes a memory for storing therein second block data at an interval of a time difference while it uses a part of a storage area of first block data having multiple pieces of frame data each having data having a predetermined length as one unit, and an error correcting portion configured to subject the first block data and the second block data each read out from the memory to error correction.

### BACKGROUND OF THE INVENTION

1. Field of the Invention

The present invention relates to an error correcting apparatus for correcting an error(s) contained in data, a method of controlling a memory of the error correcting apparatus, and an optical disc recording/reproducing apparatus having the error correcting apparatus.

2. Description of the Related Art

For example, as typified by a Blu-ray Disc (registered trademark: hereinafter referred to as “a BD” for short), an optical disc which can record therein data having a large data capacity exceeding 20 GB (“B” represents “a byte”), and a recording/reproducing apparatus for recording/reproducing the large-capacity data are distributed to the market.

In particular, since the large-capacity data is densely recorded in the BD, a burst error or the like is easy to occur in the large-capacity data. For this reason, in the BD, each of a Long Distance Code (LDC) and a Burst Indicator Subcode (BIS) is used as an Error Correcting Code (ECC). The stronger error correction can be carried out by using these codes. This technique, for example, is described in Japanese Patent Laid-Open No. 2007-12202.

Now, in a phase of correction of the error(s), the data the error(s) in which is to be corrected is temporarily stored in (written to) a memory, and after completion of the correction of the error(s), the data the error(s) in which is (are) stored in the memory again. At this time, in general, two memories having the same storage capacity are used for the LDC block data, and the error is corrected while the two memories are alternately switched over to each other. This technique, for example, is described in Japanese Patent Laid-Open Nos. 2006-190346 and 2007-59001.

Basically, while one memory stores therein one piece of LDC block data, the other memory reads out the LDC block data previously stored. It is noted that since an amount of BIS block data is less than an amount of LDC block data, the BIS block data is stored in one memory different from each of the two memories described above.

### SUMMARY OF THE INVENTION

An increase of the recording capacity of the optical disc is desired along with the promotion of the high image quality in a television broadcasting, a video camera or the like. The physical standard, the file standard and the application standard of the BD are improved so as to meet such a desire. Thus, an amount of one piece of LDC block data increases whenever such standards follow the generation. Therefore, the memory capacity which is used in the phase of the correction of the error(s) also increases.

In recent years, the development of an error correcting apparatus, a method of controlling a memory of the same, and an optical disc recording/reproducing apparatus having the same each being capable of correcting an error(s) by using a memory having a low memory capacity has been desired from a viewpoint of a cost.

The present invention has been made in order to solve the problems described above, and it is therefore desirable to provide an error correcting apparatus, a method of controlling a memory of the same, and an optical disc recording/reproducing apparatus having the same each being capable of correcting an error(s) by using a memory having a low memory capacity.

In order to attain the desire described above, according to an embodiment of the present invention, there is provided an error correcting apparatus including: a memory for storing therein second block data at an interval of a time difference while it uses a part of a storage area of first block data having multiple pieces of frame data each having data having a predetermined length as one unit; and an error correcting portion configured to subject the first block data and the second block data each read out from the memory to error correction. The memory carries out alternately: a first operation for successively reading out the multiple pieces of frame data which the first block data stored has in a row direction, and successively storing the multiple pieces of frame data which the second block data has in an empty area obtained after the reading-out in the row direction in conjunction with the reading-out; and a second operation for successively reading out the multiple pieces of frame data which the second block data has and which is stored in the first operation in a column direction, and successively storing the multiple pieces of frame data which the first block data has in an empty area obtained after the reading-out in the column direction in conjunction with the reading-out.

According to another embodiment of the present invention, there is provided a method of controlling a memory of an error correcting apparatus including a memory for storing therein second block data at an interval of a time difference while it uses a part of a storage area of first block data having multiple pieces of frame data each having data having a predetermined length as one unit, the error correcting apparatus serving to subject the first block data and the second block data each read out from the memory to error correction. The control method includes the steps of: successively reading out the multiple pieces of frame data which the first block data stored has in a row direction, and successively storing the multiple pieces of frame data which the second block data has in an empty area obtained after the reading-out in the row direction in conjunction with the reading-out; and successively reading out the multiple pieces of frame data which the second block data has and which is stored in the first operation in a column direction, and successively storing the multiple pieces of frame data which the first block data has in an empty area obtained after the reading-out in the column direction in conjunction with the reading-out.

According to still another embodiment of the present invention, there is provided an optical disc recording/reproducing apparatus including: an optical pickup portion configured to record data in an optical disc by using a light having a previously prescribed wavelength, and read out the data from the optical disc; an error correcting apparatus for subjecting the date which is to be recorded in the optical disc and the data which is read out from the optical disc by the optical pickup portion and which is to be reproduced to error correction; a recording system for coding the data which is to be recorded and which is subjected to the error correction by the error correcting apparatus; and a reproducing system for decoding the data which is to be reproduced before the error correction carried out by the error correcting apparatus. The error correcting apparatus includes: a memory for storing therein second block data at an interval of a time difference while it uses a part of a storage area of first block data having multiple pieces of frame data each having data having a predetermined length as one unit; and an error correcting portion configured to subject the first block data and the second block data each read out from the memory to error correction. The memory carries out alternately: a first operation for successively reading out the multiple pieces of frame data which the first block data stored has in a row direction, and successively storing the multiple pieces of frame data which the second block data has in an empty area obtained after the reading-out in the row direction in conjunction with the reading-out; and a second operation for successively reading out the multiple pieces of frame data which the second block data has and which is stored in the first operation in a column direction, and successively storing the multiple pieces of frame data which the first block data has in an empty area obtained after the reading-out in the column direction in conjunction with the reading-out.

In the error correcting apparatus according to the embodiment of the present invention, the memory carries out alternately the first operation for successively reading out the multiple pieces of frame data which the first block data stored has in the row direction, and successively storing the multiple pieces of frame data which the second block data has in the empty area obtained after the reading-out in the row direction in conjunction with the reading-out, and the second operation for successively reading out the multiple pieces of frame data which the second block data has and which is stored in the first operation in the column direction, and successively storing the multiple pieces of frame data which the first block data has in the empty area obtained after the reading-out in the column direction in conjunction with the reading-out.

On the other hand, the error correcting portion subjects the first block data and the second block data each read out from the memory to the error correction.

As set forth hereinabove, according to the present invention, the error correction can be carried out by using the memory having the low-memory capacity.

### BRIEF DESCRIPTION OF THE DRAWINGS

FIG. 1 is a block diagram showing a configuration of an optical disc recording/reproducing apparatus according to an embodiment of the present invention;

FIG. 2 is a schematic diagram showing a structure of LDC block data;

FIG. 3 is a schematic diagram showing a structure of BIS block data;

FIG. 4 is a schematic diagram showing a structure of ECC block data;

FIG. 5 is a schematic diagram showing frame data shown in FIG. 4;

FIG. 6 is a block diagram showing a configuration of an error correcting circuit according to according to another embodiment of the present invention;

FIG. 7 is a schematic diagram showing an example of the frame data;

FIGS. 8A to 8C are respectively schematic diagrams showing definitions of internal frame data and error correction data in the error correcting circuit according to the another embodiment of the present invention;

FIG. 9 is a schematic diagram showing a structure of a storage area in a data memory in the error correcting circuit according to the another embodiment of the present invention;

FIG. 10 is a schematic diagram showing a first storage area shown in FIG. 9;

FIGS. 11A and 11B are respectively schematic diagrams showing a state in which the LDC block data is stored in the first storage area shown in FIG. 10;

FIG. 12 is a schematic diagram showing a second storage area shown in FIG. 9;

FIGS. 13A and 13B are respectively schematic diagrams showing the case where frame data is stored in the second storage area shown in FIG. 12 in a column direction;

FIG. 14 is a schematic diagram showing a storage area of a pointer memory in the error correcting circuit according to the another embodiment of the present invention;

FIG. 15 is a timing chart of error correction in the error correcting circuit according to the another embodiment of the present invention;

FIG. 16 is a schematic diagram showing a structure of a memory of a general error correcting apparatus;

FIGS. 17A and 17B are respectively a schematic diagram showing a state of the data memory in the error correcting circuit according to the another embodiment of the present invention, and a schematic diagram showing a state of the pointer memory in the error correcting circuit according to the another embodiment of the present invention;

FIGS. 18A to 18P are respectively schematic diagrams explaining a method of controlling the data memory according to still another embodiment of the present invention; and

FIG. 19 is a flow chart explaining an operation for storing internal frame data in the data memory, and an operation for reading out the error correction data from the data memory in the method of the controlling the data memory according to the still another embodiment of the present invention.

### DETAILED DESCRIPTION OF THE PREFERRED EMBODIMENTS

The preferred embodiments of the present invention will be described in detail hereinafter with reference to the accompanying drawings. It is noted that the description will be given below in accordance with the following order.

1. Configuration of Optical Disc Recording/Reproducing Apparatus 1

2. Configuration of Error Correcting Circuit 35

3. Operation of Error Correcting Circuit 35

4. Method of Controlling Data Memory 351 of Error Correcting Circuit 35

Prior to descriptions of embodiments of the present invention, a correspondence relationship between constituent elements of the present invention, and constituent elements of the embodiments will now be described.

An error correcting apparatus of the present invention corresponds to an error correcting circuit 35. A memory of the error correcting apparatus of the present invention corresponds to a data memory 351 of the error correcting circuit 35.

A pointer holding portion of the error correcting apparatus of the present invention corresponds to a pointer memory 354 of the error correcting circuit 35. A pointer generating portion of the error correcting apparatus of the present invention corresponds to a first address circuit 352 of the error correcting circuit 35. An addressing portion of the error correcting apparatus of the present invention corresponds to a second address circuit 353 and a fourth address circuit 356 of the error correcting circuit 35. Also, a memory addressing portion of the error correcting apparatus of the present invention corresponds to a first address circuit 352 and a third address circuit 355 of the error correcting circuit 35.

First block data in the error correcting apparatus of the present invention, for example, corresponds to k-th (k=1, 2, . . . ) LDC block data in the error correcting circuit 35. Second block data in the error correcting apparatus 35 of the present invention, for example, corresponds to (k+1)-th LDC block data in the error correcting circuit 35.

### 1. Configuration of Optical Disc Recording/Reproducing Apparatus 1

Firstly, an entire configuration of the optical disc recording/reproducing apparatus according to an embodiment of the present invention will be described.

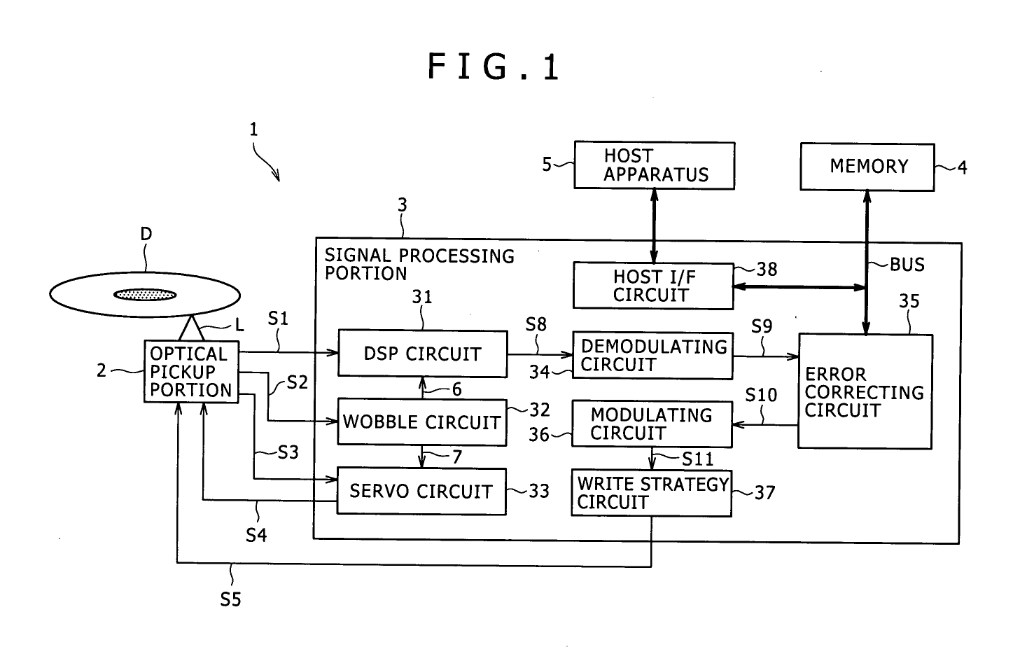

FIG. 1 is a block diagram showing a configuration of the optical disc recording/reproducing apparatus according to an embodiment of the present invention. Only a main portion of the optical disc recording/reproducing apparatus is schematically shown in FIG. 1.

The optical disc recording/reproducing apparatus 1 includes an optical pickup portion 2, a signal processing portion 3, and a memory 4. In this embodiment, the optical disc recording/reproducing apparatus 1 may include a host apparatus 5 which will be described later.

The signal processing portion 3 described above includes a Digital Signal Processing (DSP) circuit 31, a wobble circuit 32, a servo circuit 33, a demodulating circuit 34, the error correcting circuit 35, a modulating circuit 36, a write strategy circuit 37, and a host I/F circuit 38.

In the following description, a BD is given as an optical disc D, and the recording/reproducing apparatus for the BD is given as the optical disc recording/reproducing apparatus 1. In this case, the optical disc recording/reproducing apparatus 1 can treat video data and sound data which comply with the BD standard.

A Moving Picture Experts Group (MPEG)-2, an MPEG-4, MPEG-4 Part 10 Advanced Video Coding (AVC)/H.264, for example, correspond to codec for the video data. Linear Pulse Code Modulation (LPCM), and Dolby Digital (registered trademark), for example, correspond to the codec for the sound data. The optical disc recording/reproducing apparatus 1 corresponds to an Advanced Access Content System (AACS) as well for protecting a copy right.

Main functions of the optical disc recording/reproducing apparatus 1 will now be described. Firstly, the optical disc recording/reproducing apparatus 1 has a function of recording (referred to as “writing” as well) data (referred to as “user data” as well) in the optical disc D as a recording medium. Secondly, the optical disc recording/reproducing apparatus 1 has a function of reading out the data from the optical disc D to reproduce the data. Thirdly, the optical disc recording/reproducing apparatus 1 has a function of carrying out error correction for the data by using the error correcting circuit 35.

Error correction coding (referred to as “ECC coding”) and error correction decoding (referred to as “ECC decoding”) which will be described later are carried out in the error correction. It is noted that in the optical disc recording/reproducing apparatus 1, the data is processed in units of 64 KB.

### 1.1. Optical Disc D

The optical disc D corresponds to any one of a Read Only Memory (ROM) type optical disc, a Recordable type optical disc, and a Rewritable type optical disc.

The data is previously recorded in the ROM type optical disc D. A plurality of pits (not shown) are formed on a substrate (not shown) of the ROM type optical disc D. These pits play a part of the video data and the sound data. A circumferential minimum pit length is 0.149 μm, and a track pitch is 0.32 μm.

On the other hand, in the recordable type optical disc D, the data can be written either to an in-groove or to an on-groove by utilizing a phase change occurring between a crystal phase and an amorphous phase through radiation of a laser beam L. A helical continuous groove (not shown) is formed on a substrate of the recordable type optical disc D. For the purpose of recording addresses for identifying a track position on the optical disc D, the groove is wobble-modulated. The wobble modulation is obtained by combining Minimum Shift Keying (MSK) modulation and Saw Tooth Wobble (STW) modulation with each other.

Although the rewritable type optical disc D has basically the same structure as that of the recordable type optical disc D, the writing and erasing of the data can be carried out multiple times in the rewritable type optical disc D.

The optical disc D is rotated either at a Constant Linear Velocity (CLV) or at a Constant Angular Velocity (CVA) while tracking and focusing are controlled by the drive control made by a driving portion (not shown) having a motor and the like.

Although which type of optical disc D may be used in the optical disc recording/reproducing apparatus 1, for the sake of simplicity of the description, it is assumed that either the recordable type optical disc D or the rewritable optical disc D is used in the optical disc recording/reproducing apparatus 1.

### 1.2. Optical Pickup Portion 2

In a phase of reproduction, the optical pickup portion 2 has a function of reading out the data recorded in the optical disc D in the form of an optical signal, and converting the optical signal into an electric signal as analog data.

Specifically, the optical pickup portion 2 is disposed in a position facing the optical disc D, and can be moved in a radial direction of the optical disc D. The optical pickup portion 2 radiates a laser beam L having a wavelength of about 405 nm to a recording surface of the optical disc D, thereby reading out the data from the optical disc D while it carries out the focus control and the tracking control in accordance with a servo signal S4 inputted thereto from a servo circuit 33. At this time, the optical pickup portion 2 reads out a change of an intensity of a light (reflected light) made incident to a photodiode IC (not shown) (hereinafter referred to as “a PDIC” for short) in the form of an electric signal. Also, the optical pickup portion 2 outputs a resulting electric signal in the form of an RF signal (regenerative signal) S1 to the DSP circuit 31.

On the other hand, the optical pickup portion 2 detects a signal generated by the wobble by using the PDIC, and outputs the signal thus detected in the form of a wobble signal S2 to the wobble circuit 32.

In addition, the optical pickup portion 2 detects both a tracking error signal and a focus error signal by using the PDIC, and outputs both the tracking error signal and the focus error signal thus detected in the form of an error signal S3 to the servo circuit 33.

In a phase of the recording, the optical pickup portion 2 has a function of converting an electric signal inputted thereto from the signal processing portion 3 into an optical signal, and recording the resulting optical signal in the form of data in the optical disc D.

Specifically, the optical pickup portion 2 radiates the laser beam L as the optical signal to the recording surface of the optical disc D while it carries out the control for the radiated intensity of the laser beam L, the control for a pulse waveform of the laser beam L, and the like in accordance with a write strategy signal S5 inputted thereto from the write strategy circuit 37. Similarly to the case of the phase of the reproduction, the optical pickup portion 2 also carries out the focus control and the tracking control in accordance with the servo signal S4 described above. At this time, the optical pickup portion 2 moves an optical head to an address, on the optical disc. D, set in the user data. As a result, a plurality of marks (pits) are formed in addresses specified on the optical disc D, respectively, thereby writing the user data.

The signal processing portion 3 mainly includes a drive control system, a reproduction system and a recording system. In this case, an outline of the signal processing portion 3 will be described below while it is made to correspond to the drive control system, the reproduction system and the recording system.

### 1.3. Drive Control System

The drive control system is composed of the wobble circuit 32 and the servo circuit 33. The write strategy circuit 37 can also be substantially regarded as being included in the drive control system.

The wobble circuit 32 subjects the wobble signal S2 inputted thereto from the optical pickup portion 2 to Analog/Digital (A/D) conversion. Since the wobble signal S2 is wobble-modulated, the wobble circuit 32 demodulates the wobble signal S2 by using both the MSK and the STW. Also, the wobble circuit 32 creates address data S6 about the addresses on the optical disc D based on the wobble signal S2 thus demodulated, and outputs the address data S6 thus created to the DSP circuit 31.

In addition, the wobble circuit 32 creates a clock signal S7 by using a Phase Locked Loop (PLL) circuit (not shown) or the like in accordance with the wobble signal S2, and outputs the clock signal S7 thus created to the servo circuit 33. Also, the clock signal S7 is a signal synchronously with which the optical disc D is rotated either at the CLV or at the CAV with the wobble signal S2 being synchronized with a reference clock signal.

The servo circuit 33 basically carries out the drive control for the optical pickup portion 2, and the rotation control for the optical disc D.

Specifically, the servo circuit 33 creates a servo signal S4 in accordance with the error signal S3 and the clock signal S7, and outputs the servo signal S4 thus created to the optical pickup portion 2. The servo signal S4 is a signal in accordance with which both the focus control and the tracking control are carried out.

In addition thereto, the servo circuit 33, for example, outputs a signal which is used to instruct a motor (not shown) for rotating the optical disc D to start or stop the rotation to the motor on the basis of a control instruction from the host apparatus 5.

### 1.4. Reproducing System

The reproducing system is composed of the DSP circuit 31, the demodulating circuit 34 and the error correcting circuit 35.

The DSP circuit 31 amplifies the RF signal S1 inputted thereto from the optical pickup portion 2, and subjects the RF signal S1 thus amplified to the A/D conversion. Also, the DSP circuit 31 subjects the digitized RF signal S1 to equalizing processing of, for example, Partial Response Maximum Likelihood (PRML), thereby creating binary data (referred to as “a data bit string” as well) expressed by binary digit data of “0” or “1.” In addition, the DSP circuit 31 adds the address data S6 inputted thereto from the wobble circuit 32 to the binary data, and outputs resulting data in the form of new binary data S8 to the demodulating circuit 34.

The demodulating circuit 34 viterbi-demodulates the binary data S8 inputted thereto from the DSP circuit 31 by, for example, using a viterbi algorithm, and outputs resulting data in the form of regenerative data S9 to the error correcting circuit 35. It is noted that the regenerative data S9 is binary data containing therein the binary data as the video data and the sound data, and the address data S6 created by the wobble circuit 32.

The error correcting circuit 35 ECC-demodulates the regenerative data S9 inputted thereto from the demodulating circuit 34 in the phase of the reproduction. At this time, the error correcting circuit 35 carries out both a logic arithmetic operation using a parity added to the regenerative data S9, and de-interleave processing, thereby correcting an error(s) contained in the regenerative data S9. After that, the error correcting circuit 35 outputs the regenerative data S9 the error(s) in which is (are) corrected to the host I/F circuit 38. It is noted that the error correcting circuit 35 may output the regenerative data S9 the error(s) in which is (are) corrected to the memory 4.

### 1.5. Recording System

The recording system is composed of the error correcting circuit 35, the modulating circuit 36, and the write strategy circuit 37.

When the original data which is to be recorded in the optical disc D (referred to as “user data” as well) is inputted either from the host I/F circuit 38 or from the memory 4 to the error correcting circuit 35 in a phase of the recording, the error correcting circuit 35 carries out both ECC coding and the interleave processing for the original data. After that, the error correcting circuit 35 outputs the data thus ECC-coded in the form of recording data S10 to the demodulating circuit 36.

The modulating circuit 36, for example, subjects the recording data S10 inputted thereto from the error correcting circuit 35 to 1-7 Parity preserve/Prohibit repeated minimum transition length (PP) modulation, and outputs a resulting data in the form of a modulated signal S11 to the write strategy circuit 37.

The write strategy circuit 37 adjusts a modulation waveform of the laser beam L for the purpose of recording the modulated signal S11 inputted thereto from the modulating circuit 36 in the form of data in the optical disc D.

Specifically, the write strategy circuit 37 creates data on the radiation intensity of the laser beam L, and a pulse waveform of the laser beam L in accordance with the modulated signal S11 in terms of recording compensation, and outputs the data thus created in the form of a write strategy signal S5 to the optical pickup portion 2.

The memory 4 can store therein various kinds of data such as the data used in the signal processing in the signal processing portion 3. The exchange of the data among the memory 4, the error correcting circuit 35, and the host I/F circuit 38 is carried out through an internal bus BUS.

The host apparatus 5, for example, is a Personal Computer (called “PC”) or a digital video camera.

For example, when the PC is connected to the host I/F circuit 38, the PC issues a control instruction to the signal processing portion 3, and the regenerative data S9 the error(s) in which is (are) corrected is subjected either to image processing or to sound processing in the PC. For example, this also applies to the case where the digital video camera is connected to the host I/F circuit 38.

### LDC Block Data

In the recording system, the error correcting circuit 35 carries out the ECC coding for adding the parity to the user data. At this time, both the LDC block data and the BIS block data are created, and the ECC block data is created in accordance with both the LDC block data and the BIS block data.

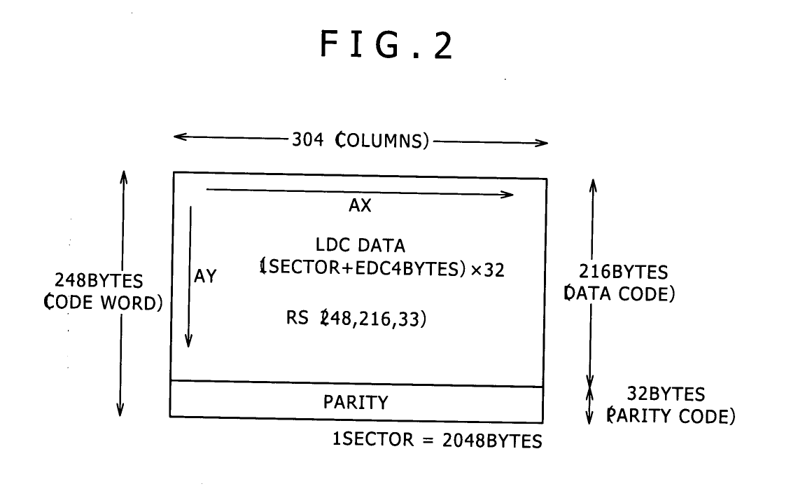

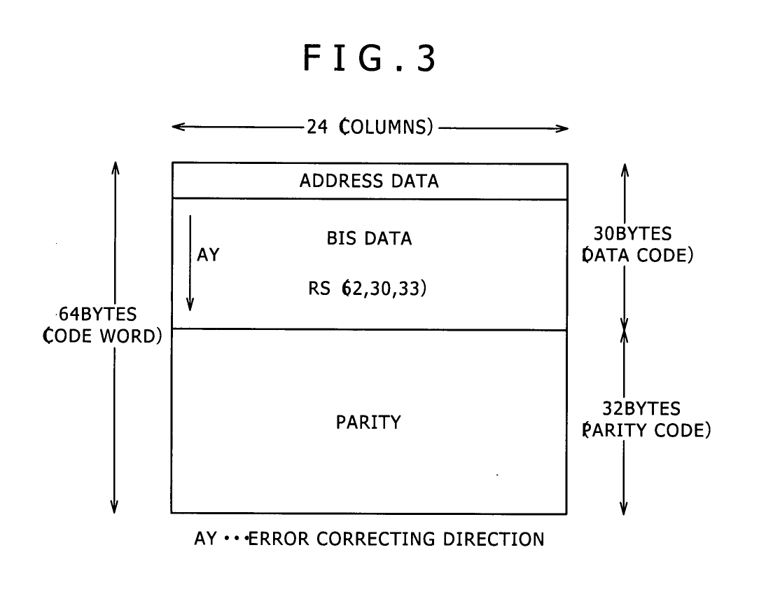

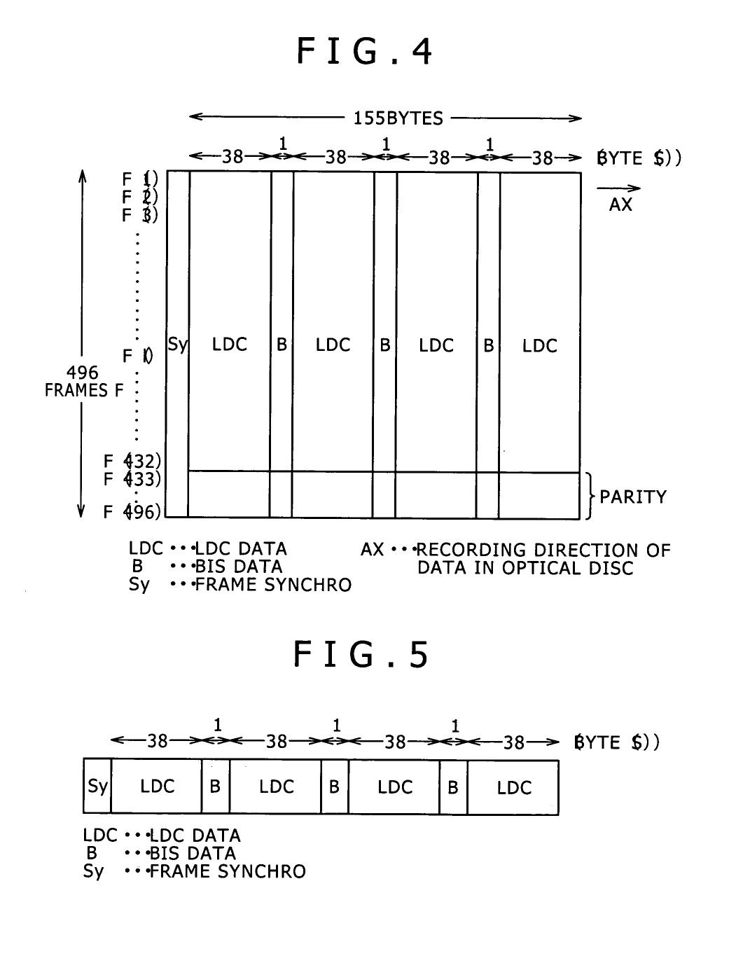

Firstly, the LDC block data will be described with reference to FIG. 2, and the BIS block data will be described with reference to FIG. 3. After that, the ECC block data will be described with reference to FIG. 4.

FIG. 2 is a schematic diagram showing a structure of the LDC block data. Specifically, an Error Detection Code (EDC) having a data capacity of 4 B is added to the (user) data having a data capacity of 2048 B as one sector. That is to say, addition data having a data capacity of 2052 B is created. The addition of the EDC to one sector is carried out for 32 sectors (=64 KB). The data for 32 sectors is referred to as “LDC data.”

Also, the data for 32 sectors to which the EDC is added is coded (referred to as “LDC coding”), thereby creating one piece of LDC block data shown in FIG. 2. As shown in FIG. 2, the LDC block data is composed of a block of 248 B×304 columns (=65664 B), and the parity (LDC) having a data capacity of 32 B is added every data having a data capacity of 216 B.

The data having a data capacity of 216 B is suitably referred to as “a data code,” and the parity having a data capacity of 32 B is suitably referred to as “a parity code.” Also, the data having a data capacity of 248 B to which the parity is added is referred to as “a code word.” A minimum unit of the code word, that is, 1 byte is referred to as “a symbol” as well. Similarly to this, the expression described above is also used for each of the BIS block data and the ECC block data.

It is noted that in the case of the LDC coding, a Read Solomon Code of RS(248, 216, 33) is used. Thus, in the LDC coding, the code word has a data capacity of 248 B, the data code has a data capacity of 216 B, and a minimum inter-code distance is 33.

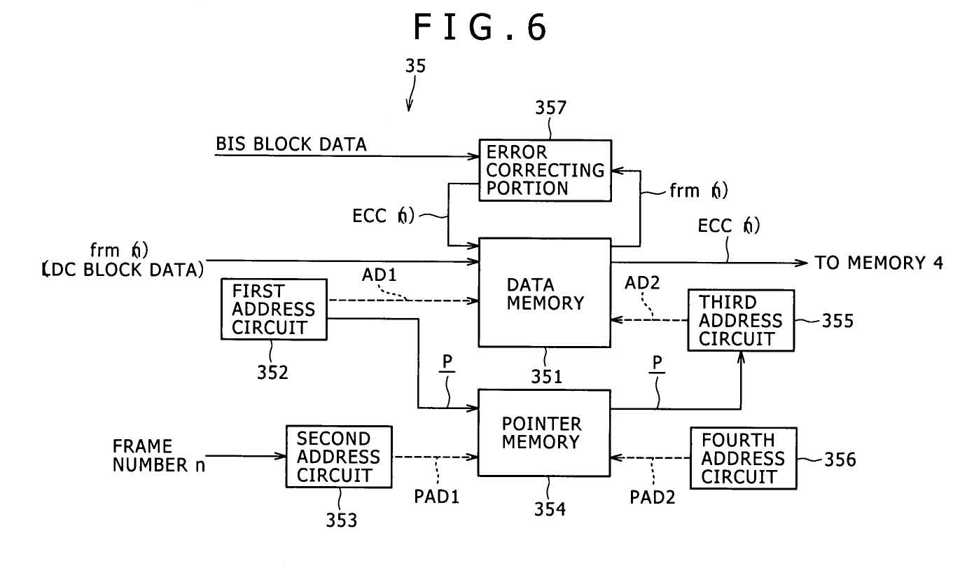

It is noted that a direction of recording of the data in the optical disc D is a direction indicated by an arrow AX in FIG. 2. Also, an error correcting direction, in other words, a direction of storing (reading) of the data in a memory (a memory 351 shown in FIG. 6) provided inside the error correcting circuit 35 is a direction indicated by an arrow AY in FIG. 2.

### BIS Block Data

FIG. 3 is a schematic diagram showing a structure of the BIS block data. Specifically, the address data is added to the control data, thereby creating the data code having a data capacity of 30 B. For example, when the ROM type optical disc having no wobble is used, the address data is added to the control data. Also, the data (referred as “BIS data”) having a data capacity of 30 B×24 (=720 B) is coded (referred to as “BIS coding”), thereby creating one piece of BIS block data shown in FIG. 3.

As shown in FIG. 3, the BIS block data is composed of the block having a data capacity of 62 B×24 (=1488 B), and the parity (BIS) having a data capacity of 32 B is added every data code having a data capacity of 30 B.

It is noted that in the case of the BIS coding, the Read Solomon code having RS(62, 30, 33) is used. Thus, in the case of the BIS coding, the code word has a data capacity of 62 B, the data code has a data capacity of 30 B, and the minimum inter-code distance is 33.

### ECC Block Data

FIG. 4 is a schematic diagram showing a structure of the ECC block data. The LDC block data and the BIS block data are each interleaved, thereby creating one piece of ECC block data shown in FIG. 4. The ECC block data has a capacity of 155 B×496 frames.

A frame synchro is synchronous data representing a head of each of the frame data. A frame number within the ECC block data can be detected in accordance with both a combination of synchro IDs contained in the frame synchro, and an Address Unit Number (AUN) contained in the BIS data.

Here, the frame data of a frame number 1 is expressed in the form of “frame data F(l)” where l=1 to 496.

The frame data F(1) to F(432) correspond to a row containing therein the LDC data and the BIS data. The frame data F(433) to F(496) are the parity of the LDC and BIS block data.

FIG. 5 is a schematic diagram showing the frame data illustrated in FIG. 4. As shown in FIG. 5, for example, in the frame data F(1), the LDC data, the BIS data, the LDC data, the BIS data, the LDC data, the BIS data, and the LDC data are arranged in order after the frame synchro. That is to say, a physical cluster having a data capacity of 155 B is composed of four pieces of LDC data having a data capacity of 38 B, and three pieces of BIS data having a data capacity of 1 B.

It is noted that each of the block data shown in FIGS. 2 to 4, respectively, represents an image when being stored in the memory. The creation of each of the block data, for example, is carried out by using the memory 4. Although not illustrated, each of the block data may also be created by using the memory provided inside the error correcting circuit 35. The ECC block data is created in accordance with the user data, and becomes the recording data S10 shown in FIG. 1. Finally, the user data is recorded in the form of the write strategy signal S5 in the optical disc D.

Thus, the error correcting circuit 35 subjects the data which is to be recorded in the optical disc D and the data which is to be read out from the optical disc D by the optical pickup portion 2 and which is to be reproduced to the error correction. Here, as will be described below, the error correcting circuit 35 includes a data memory 351 for storing therein a second block data at the interval of a time difference while it uses at least a part of a storage area of first block data having multiple pieces of frame data each having data having a predetermined length as one unit, and an error correcting portion 357 for subjecting the first block data and the second block data each read out from the data memory 351 to error correction. Also, as will be described below, the data memory 351 carries out alternately a first operation for successively reading out the multiple pieces of frame data which the first block data stored has in a row direction, and successively storing the multiple pieces of frame data which the second block data has in an empty area obtained after the reading-out in the row direction in conjunction with the reading-out, and a second operation for successively reading out the multiple pieces of frame data which the second block data has and which is stored in the first operation in a column direction, and successively storing the multiple pieces of frame data which the first block data has in an empty area obtained after the reading-out in the column direction in conjunction with the reading-out.

### 2. Configuration of Error Correcting Circuit 35

In the reproducing system, the ECC block data read out from the optical disc D is inputted in the form of the regenerative data S9 shown in FIG. 1 to the error correcting circuit 35. Then, the error correcting circuit 35 extracts both the LDC block data and the BIS block data from the regenerative data S9, and stores both the LDC block data and the BIS block data in the data memory 351 while it de-interleaves both the LDC block data and the BIS block data. After that, the error correcting circuit 35 carries out the error correction for the user data by using the parities of both the LDC block data and the BIS block data.

Hereinafter, a configuration of the error correcting circuit 35 of the reproducing system will be described with reference to FIG. 6. However, it is assumed in the following description that the extraction of both the LDC block data and the BIS block data from the regenerative data S9 has already been completed.

FIG. 6 is a block diagram showing the configuration of the error correcting circuit 35 according to another embodiment of the present invention. In FIG. 6, arrows each indicated by a heavy line represent the data bus and the flow of the data. Also, arrows each indicated by a broken line represent the address bus and the flow of the address. However, only a processing system for the LDC block data in the reproducing system is shown in FIG. 6.

An outline of the error correcting circuit 35 will now be described. As shown in FIG. 6, the error correcting circuit 35 includes the data memory 351, a first address circuit 352, a second address circuit 353, and a pointer memory 354. Also, the error correcting circuit 35 includes a third address circuit 355, a fourth address circuit 356, and the error correcting portion 357.

After the error correcting circuit 35 extracts the LDC block data from the ECC block data as the regenerative data S9, the error correcting circuit 35 temporarily stores (referred to as “buffering”) in the data memory 351, and then carries out the error correction for the data in the error correcting portion 357. The data stated herein points to the LDC data (refer to FIG. 2) and the BIS data (refer to FIG. 3). It is noted that although the error correcting circuit 35 temporarily buffers the BIS block data as well thus extracted, the BIS block data is stored in a memory (not shown).

In this connection, “the frame (data)” generally points to the block having a set of multiple bit data as a bundle. In particular, in the ECC block data, “the frame (data),” as shown in FIGS. 4 and 5, points to the data composed of synchro-data, four pieces of LDC data, and three pieces of BIS data.

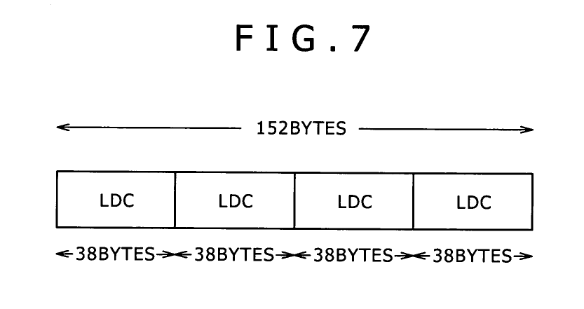

In the another embodiment, a set of the bit data having a predetermined length is defined as follows. Specifically, when the error correcting circuit 35 carries out the de-interleaving, a Recording Frame complying with the BD standard is created. It is noted that one recording frame has a data capacity of 155 B, and the ECC block data having both the LDC block data and the BIS block data is composed in the recording frame for 1 Recording Unit Block (RUB). Also, the LDC block data is extracted from the recording frame, and 496 blocks having a data capacity of 152 B and shown in FIG. 7 are created. In this case, the block having a data capacity of 152 B is also referred to as “the frame data,” and is described in the form of the frame data frame(i) (i=0, 1, . . . , 495).

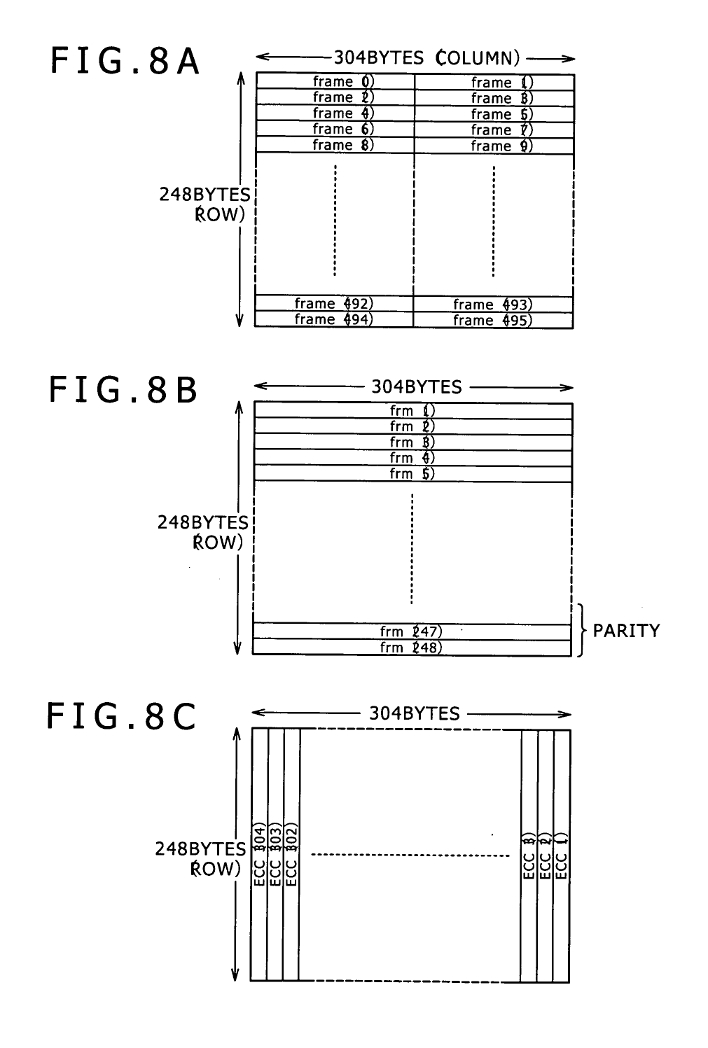

FIGS. 8A to 8C are respectively diagrams showing definitions of internal frame data and error correction data in the error correcting circuit 35 according to the another embodiment of the present invention. 496 frame data frame is arranged in the manner as shown in FIG. 8A. Specifically, two pieces of frame data frame(i), i.e., even number-th frame data frame(i) (i=0, 2, . . . ), and odd number-th frame data frame(i) (i=1, 3, . . . ) are arranged in each of rows, thereby creating block data having a data capacity of 248×304 B. This block data is also simply referred to as “LDC block data.”

In the another embodiment, as shown in FIG. 8B, the even number-th frame data frame and the odd number-th frame data frame in each of the rows are treated as one piece of data. Data for two pieces of frame data frame is referred to as “internal frame data,” and is suitably described in the form of “internal frame frm (n)” as well (n=1, 2, . . . , nₘₐₓ (=248)).

Although the. LDC block data shown in FIG. 8B is stored in the data memory 351, 217-th to 248-th interval frame data frm(217) to frm(248) correspond to the parity. For this reason, when the LDC block data is read out, as shown in FIG. 8C, the data having a data capacity of 248 B and belonging to one column is read out as a bundle in a column direction.

For this reason, the data having a data capacity of 248 B and belonging to corresponding one of the columns as shown in FIG. 8C is referred to as “the error correction data,” and is suitably described in the form of “the error correction data ECC(n)” (n=1, 2, . . . , nₘₐₓ (=304)).

When there is no need for distinguishing the internal frame data and the error correction data from each other, both the internal frame data and the error correction data are simply referred to as “the frame data” as well.

The data memory 351 is preferably a static RAM (SRAM) in consideration of a speed of an access to the memory. A storage capacity of the data memory 351 is a capacity with which one piece of LDC block data, and a predetermined number of pieces of frame data composing the one piece of LDC block data can be stored. In other words, the data memory 351 has a main storage area in which one piece of LDC block data is stored, and a redundant storage area in which a predetermined number of code words are stored.

During the buffering, the data memory 351 does not store therein one piece of LDC block data at a time, but stores therein one piece of LDC block data in units of the internal frame data for two pieces of frame data frame (refer to FIG. 7). The data memory 351 stores therein the LDC block data which is extracted as the regenerative data S9 from the ECC block data and the error(s) in which is (are) to be corrected, and the frame data the error(s) in which is (are) corrected by the error correcting portion 357.

When the data memory 351 stores therein the LDC block data the error(s) in which is (are) to be corrected, the data memory 351 reads out the LDC block data concerned which is in turn outputted to the error correcting portion 357. On the other hand, when the data memory 351 stores therein the LDC block data the error(s) in which is (are) previously corrected, the data memory 351 outputs the LDC block data concerned to the memory 4.

However, in order to efficiently buffer the LDC block data by using one memory, the data memory 351 stores therein the LDC block data which is subsequently inputted thereto while it uses at least a part of the storage area for the LDC block data previously stored therein.

A first address circuit 352 specifies an address in the data memory 351 in which either the internal frame data or the LDC block data the error(s) in which is (are) corrected is to be stored, and outputs data on the address data AD1 to the data memory 351. When the first address circuit 352 specifies the address, the first address circuit 352 increments an address number in order from 1 so that the internal frame data is continuously stored either in a row direction or in a column direction in the data memory 351.

In addition, the second address circuit 353 specifies an address by using a frame number, n, and stores a pointer P indicating an address in the internal frame data created in the first address circuit 352 in a specified address in the pointer memory 354.

It is noted that the pointer P is data indicating a place, in the data memory 351, where either the internal frame data frm(n) or the error correction data ECC(n) is stored. Although the details thereof will be described later, whenever either the internal frame data frm(n) or the error correction data ECC(n) is stored in the data memory 351, the pointer P is also stored in the pointer memory 354. As a result, it is possible to grasp which of the addresses which of the internal frame data is stored in. This is carried out in order to exactly carry out the operation for storing the internal frame data frm(n) in the data memory 351 and the operation for reading out the error correction data ECC(n) from the data memory 351 even when a burst error or the like occurs.

The second address circuit 353 specifies an address in the pointer memory 354 in which the pointer P is to be stored, and outputs data on the address as address data PAD1 to the pointer memory 354.

The frame number, n, corresponds to the internal frame data frm(n), and is acquired when the detection of the synchro, and the detection of the address are carried out in the demodulating circuit 34. When the internal frame data frm(n) corresponding to the frame number, n, is inputted to the data memory 351, the frame number, n, is inputted to the pointer memory 354 in conjunction with this input operation.

The pointer memory 354 stores (holds) the pointer P in the specified address in accordance with the address data PAD1 inputted thereto from the second address circuit 353. Also, the pointer memory 354 reads out the pointer P from the specified address in accordance with the address data PAD2 inputted thereto from the fourth address circuit 356.

The pointer memory 354, for example, is composed of the SRAM. A storage capacity of the pointer memory 354 is a capacity enough to be able to store the pointers P for the internal frame data stored in the data memory 351, and thus is much smaller than that of the data memory 351.

The third address circuit 355 specifies an address which is to be read out from the data memory 351, and outputs data on the address in the form of the address data AD2 to the data memory 351. This address, for example, is also incremented in order from the address number 1 to be specified.

In addition, the third address circuit 355 reads out the pointer P from the address, in the pointer memory 354, specified by the fourth address circuit 356. Also, the third address circuit 355 reads out the error correction data ECC(n) from the data memory 351 in accordance with the pointer P.

The fourth address circuit 356 specifies an address in the pointer memory 354, and outputs data on the address in the form of the address data PAD2 from the pointer memory 354.

The error correcting portion 357 reads out the error correction data ECC(n) composing the LDC block data from the data memory 351 in order, and corrects the error(s) contained in the error correction data ECC(n).

Specifically, the error correcting portion 357 corrects the error(s) contained in the BIS block data earlier than the LDC block data, and estimates an error portion(s) within the ECC block data. Also, the error correcting portion 357 corrects the error(s) contained in the error correction data ECC(n) inputted thereto in accordance with an error value(s) in the error portion(s). It is noted that a direction of the error correction for the BIS block data is the direction indicated by the arrow AY shown in FIG. 3.

After completion of the error correction for the error correction data ECC(n), the error correcting portion 357 stores the error correction data for which the error correction is carried out in the data memory 351 again. It is noted that the error correction data ECC(n) containing therein no error is stored in the memory 4.

### 2.1. Structure of Memory Area in Data Memory 351

A structure of a memory area in the data memory 351 will now be described with reference to FIG. 9. FIG. 9 is a schematic diagram showing a structure of a storage area (memory cell array) in the data memory of the error correcting circuit 35 according to the another embodiment of the present invention.

As shown in FIG. 9, for the storage of the LDC block data having a data capacity of 304×248 B, the data memory 351 has a storage capacity of Xₘₐₓ(column)×Yₘₐₓ(row) bytes which is larger than the data capacity of the LDC block data.

For the sake of simplicity of the description, it is assumed in the another embodiment that Xₘₐₓ=Yₘₐₓ=306 B is set. Actually, a memory, for example, having a storage capacity of Xₘₐₓ=Yₘₐₓ=320 B, that is, 320×320 B is suitably used. The reason for this is because the redundant storage area previously stated is provided. It is noted that X=304 B, and Y=248 B are set so as to correspond to the structure of the LDC block data.

Although Xₘₐₓ and Yₘₐₓ can be preferably selected, values of Xₘₐₓ and Yₘₐₓ are ones allowing one piece of LDC block data to be stored, that is, ones meeting a relationship of {Xₘₐₓ, Yₘₐₓ>X} and {Xₘₐₓ, Yₘₐₓ>Y}. However, Xₘₐₓ and Yₘₐₓ have the respective values with which the storage capacity of the data memory 351 becomes equal to or smaller than (304×248 B)×2.

The reason for this is because when the storage capacity of the data memory 351 becomes equal to or larger than (304×248 B)×2, in other words, when a memory having a storage capacity exceeding the data capacity for two pieces of LDC block data is used, the error correcting circuit 35 of the another embodiment becomes similar to the general error correcting apparatus.

The data memory 351 has a first storage area ARE1 and a second storage area ARE2. The first storage area ARE1 is an area surrounded by points A, B, C, and D in FIG. 9, and a size (storage capacity) thereof is X(column)×Y(row) bytes. The second storage area ARE2 is an area surrounded by points E, F, G, and H in FIG. 9, and a size (storage capacity) thereof is Y(column)×X(row) bytes.

Both the first storage area ARE1 and the second storage area ARE2 are identical in storage capacity to each other, and thus, for example, 304 pieces of error correction data can be stored in each of the first storage area ARE1 and the second storage area ARE2. Both the first storage area ARE1 and the second storage area ARE2 overlap each other in an area surrounded by the points B, I, G, and J in FIG. 9, and this area is referred to as “a shared storage area SARE” as well.

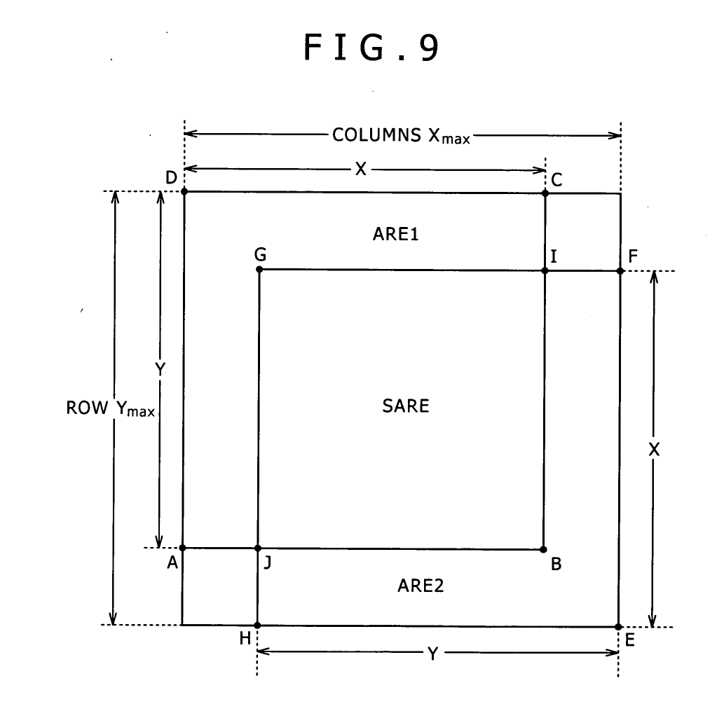

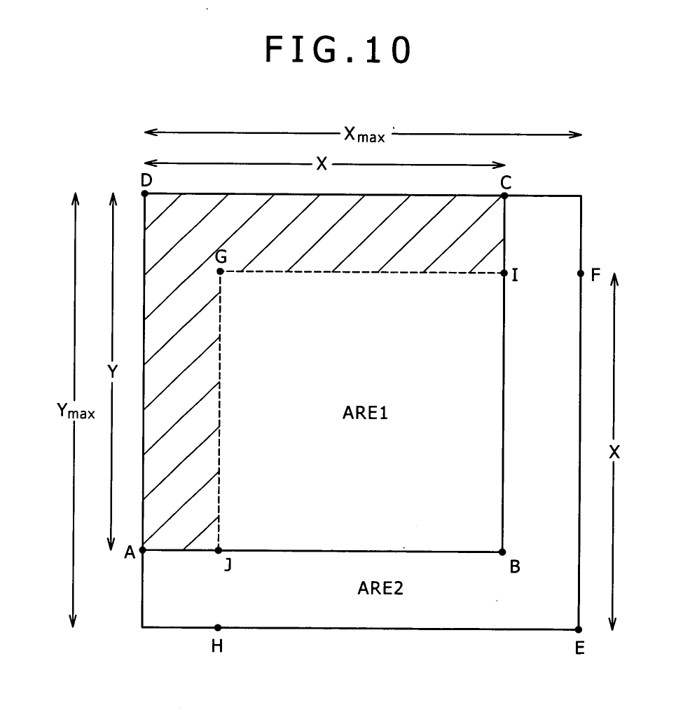

FIG. 10 is a schematic diagram showing the first storage area ARE1 shown in FIG. 9. The first storage area ARE1 corresponds to a main storage area. When 1 piece of LDC block data is stored in the second storage area ARE2 shown in FIG. 10, a rotated L-like area surrounded by the pointers A, J, G, I, C, and D corresponds to the redundant storage area. The redundant storage area in this case is shown by slant lines. Although the redundant storage area has a storage capacity corresponding to the rotated L-like area, the storage capacity which is actually used is expressed by {(Yₘₐₓ−X)×X}B. When one piece of internal frame data has a data capacity of 304 B, about two pieces of internal frame data can be stored in the redundant storage area. By using the redundant storage area, another LDC block data can be stored while the LDC block data previously stored is read out.

In the error correcting circuit 35 of the another embodiment, all it takes is that one piece of LDC block data, and a predetermined number of pieces of frame data (for example, two pieces of internal frame data) can be stored in the data memory 351. Therefore, when one piece of LDC block data is stored in the first storage area ARE1, a storage area, of the storage area of the data memory 351, other than the first storage area ARE1 can be regarded as the redundant storage area.

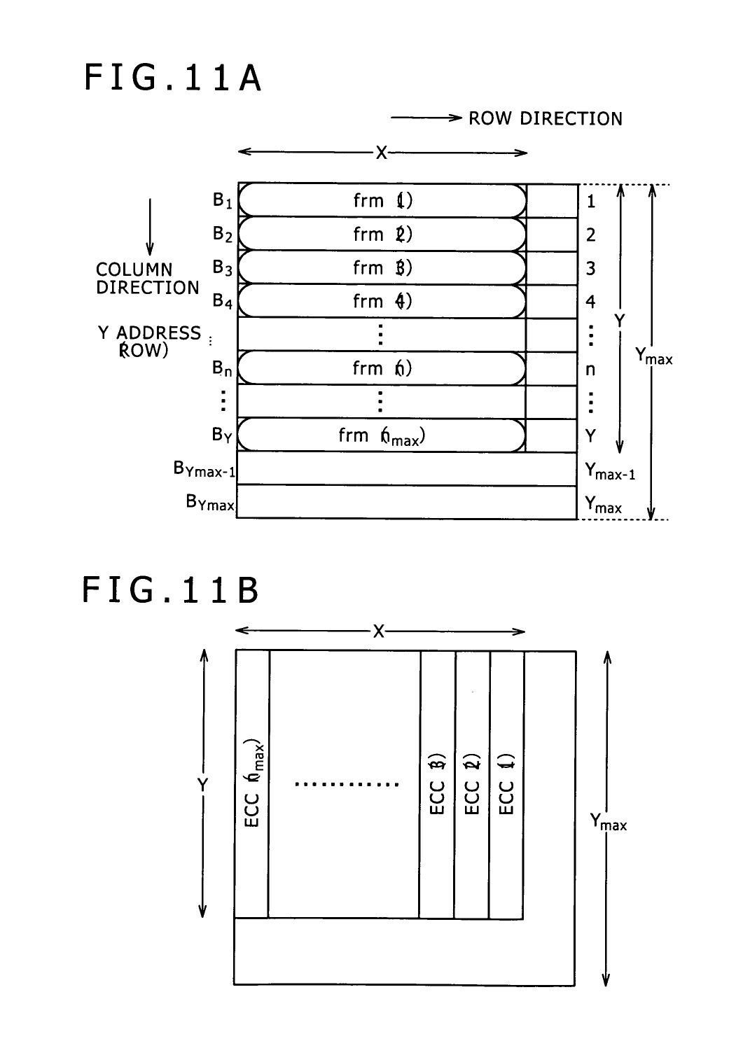

An example of a storage state of the LDC block data in the first storage area ARE1 is shown in FIGS. 11A and 11B. FIGS. 11A and 11B are respectively schematic diagrams showing a state in which the LDC block data is stored in the second storage area ARE2 shown in FIG. 10.

As shown in FIG. 11A, in the storage area of the data memory 351, address numbers B₁, B₂, . . . , Bₙ, . . . , B_{Y}, . . . , B_{Ymax}are allocated to Y addresses from the first row to Yₘₐₓ-th row, respectively.

When the internal frame data frm is stored in the first storage area ARE1, nₘₐₓ pieces (=248) of internal frame data frm(n) composing the block data is stored in order from the B₁ row in a row direction. As a result, nₘₐₓ pieces of internal frame data frm(1) to frm(nₘₐₓ) are stored in the B₁ row to the B_{Y} row, respectively.

Although details will be described later, when the error correction data is read out, as shown in FIG. 11B, nₘₐₓ (=304) pieces of error correction data ECC(1) to ECC(nₘₐₓ) with the data of one column as one unit are read out in order in a column direction.

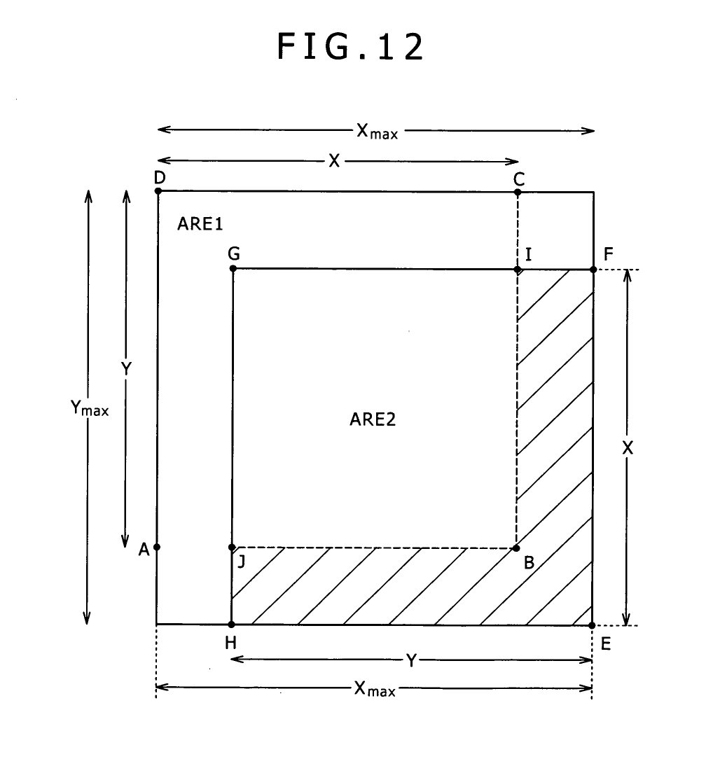

FIG. 12 is a schematic diagram showing the second storage area ARE2 shown in FIG. 9. The second storage area ARE2 corresponds to the main storage area. When the k-th LDC block data is stored in the first storage area ARE1 shown in FIG. 12, an inversed L-like area surrounded by the points E, F, I, B, J, and H corresponds to the redundant storage area. Similarly to the rotated L-like area of FIG. 10, the redundant storage area is shown by slant lines. Although the redundant storage area has a storage capacity corresponding to that area, the storage capacity which is actually used is expressed by {(Xₘₐₓ−Y)×Y}B. When one piece of internal frame data has a data capacity of 304 B, about two pieces of internal frame data can be stored in the redundant storage area. By using the redundant storage area, another LDC block data can be stored while the LDC block data previously stored is read out.

As described above, all it takes is that one piece of LDC block data, and a predetermined number of pieces of frame data (for example, two pieces of internal frame data) can be stored in the data memory 351. Therefore, when one piece of LDC block data is stored in the second storage area ARE2, a storage area, of the storage area of the data memory 351, other than the second storage area ARE2 can be regarded as the redundant storage area.

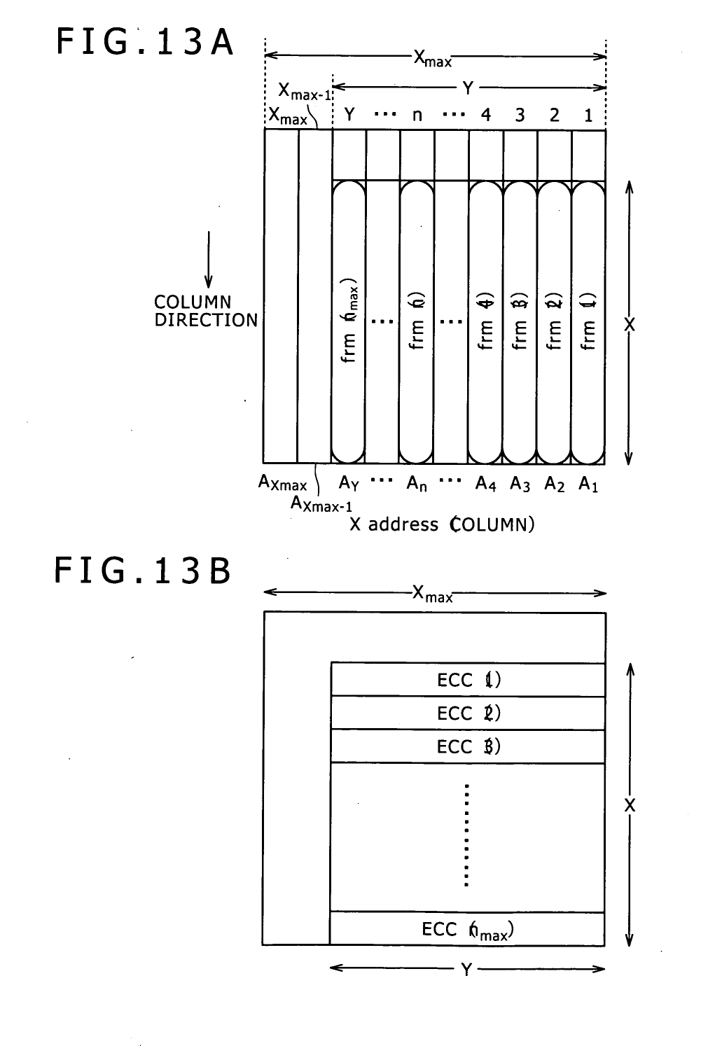

An example of a storage state of the LDC block data in the second storage area ARE2 is shown in FIGS. 13A and 13B. FIGS. 13A and 13B are respectively schematic diagrams showing a state in which the LDC block data is stored in the second storage area ARE2 shown in FIG. 12.

As shown in FIG. 13A, in the storage area of the data memory 351, address numbers A₁, A₂, . . . , Aₙ, . . . , A_{Y}, . . . , A_{Xmax} are allocated to X addresses from the first row to Xₘₐₓ-th row, respectively. It is noted that although these address numbers are allocated in such a way that the address number in which the internal frame data frm(1) is stored becomes A₁, actually, these addresses are allocated from the origin (for example, the point D: refer to FIG. 12) in the column direction.

When the internal frame data frm(n) is stored in the second storage area ARE2, nₘₐₓ (=248) pieces of internal frame data frm(n) composing the block data is stored in order from the A₁ row in the column direction. As a result, nₘₐₓ pieces of internal frame data frm(1) to frm(nₘₐₓ) composing one piece of LDC block data are stored in the A₁ column to the A_{Y} column, respectively.

Although details will be described later, when as shown in FIG. 13B, the LDC block data is read out in order to output the LDC block data to the error correcting portion 357, nₘₐₓ (=304) pieces of error correcting data ECC(1) to ECC(nₘₐₓ) with the data of one row as one unit are read out in order in the row direction.

### 3. Operation of Error Correcting Circuit 35

Firstly, a basic operation of the error correcting circuit 35 relating to the storage and the reading of the LDC block data will be described with reference to FIGS. 11A and 13A. For the purpose of making the description clear up, it is assumed that the LDC block data is stored by using only the first storage area ARE1 shown in FIG. 11A. Likewise, it is also assumed that the LDC block data is read out by using only the second storage area ARE2 shown in FIG. 13A.

### 3.1. Method of Storing LDC Block Data

A method of storing the LDC block data will be described below. However, the case where the LDC block data is assumed to be the internal frame data shown in FIG. 11A, and is stored before being inputted to the error correcting portion 357 is given as an example.

Step J1:

Firstly, the internal frame data frm(1) is stored in the B₁ row. Specifically, the first address circuit 352 specifies the address number B₁, and outputs the address number B₁ as address data AD1 to the data memory 351 (J11). Then, the data memory 351 receives the address data AD1, and stores the internal frame data frm(1) in the B₁ row (J12).

On the other hand, when a frame number 1 is inputted to the second address circuit 353, the second address circuit 353 specifies an address number C₁ in the pointer memory 354, and outputs the address number C₁ as address data PAD1 to the pointer memory 354 (J13). At this time, the first address circuit 352 stores a pointer P₁ indicating the address number B₁ in an address number C₁ in the pointer memory 354 (J14).

Step J2:

Next, the internal frame data frm(2) is stored in a B₂ row. In this case as well, similarly to the case of Step J1, the first address circuit 352 specifies an address number B₂, thereby storing the internal frame data frm(2) in the address number B₂.

Hereinafter, similarly to each of the cases of Steps J1 and J2, (nₘₐₓ−2) pieces of internal frame data frm(3) to frm(nₘₐₓ) are stored in a B₃ row to a B_{Y} row in order, respectively.

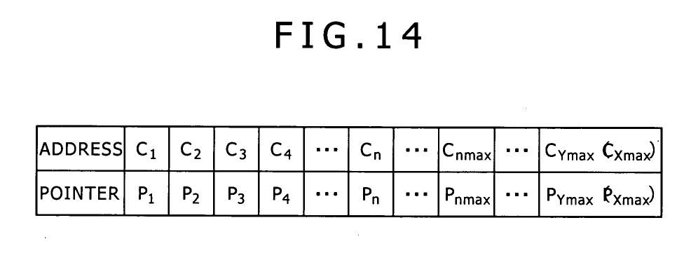

Here, a method of storing the pointer P in the pointer memory 354 will be described with reference to FIG. 14. FIG. 14 is a schematic diagram showing a storage area of the pointer memory in the error correcting circuit 35 according to the another embodiment of the present invention.

As shown in FIG. 14, the pointer memory 354 has a storage capacity allowing the pointers P for the internal frame data to be stored, that is, a storage capacity of at least Xₘₐₓ (=Yₘₐₓ)B in the case of the another embodiment. Address numbers C₁, C₂, . . . , Cₙ, . . . , Cₙₘₐₓ, . . . , C_{Ymax} (C_{Xmax}), for example, are allocated to the storage area.

The address number is incremented from C₁ to Cₙₘₐₓ or C_{Ymax} (C_{Xmax}) in order by the second address circuit 353. Also, the pointers P₁, P₂, . . . , Pₙ, . . . , Pₙₘₐₓ or P_{Ymax} (P_{Xmax}) are stored in the order of the address number.

### 3.2. Method of Reading Out LDC Block Data

A method of reading out the LDC block data will be described hereinafter. For the sake of simplicity of the description, the LDC block data is assumed to be the LDC block data shown in FIG. 13A, and nₘₐₓ pieces of internal frame data from frm(1) to frm(nₘₐₓ) are simply read out in the column direction. Actually, the LDC block data stored in the second storage area ARE2 is read out as the error correction data ECC in the row direction.

Step R1:

Firstly, the internal frame data frm(1) is read out from the A₁ column. Specifically, the third address circuit 355 specifies the address number A₁, and outputs the address number A₁ as address data AD2 to the data memory 351 (R11).

On the other hand, the fourth address circuit 356 specifies an address number C₁ in the pointer memory 354, and outputs the address number C₁ as address data PAD2 to the pointer memory 354 (R12).

Then, the third address circuit 355 reads out the pointer P₁ from the address number C₁, in the pointer memory 354, specified by the fourth address circuit 356 (R13). Also, the third address circuit 355 reads out the internal frame data frm(1) from the data memory 351 in accordance with the pointer P₁ (R14).

Step R2:

Next, the internal frame data frm is read out from the A₂ column. In this case as well, similarly to the case of Step R1, the address number A₂ is specified, thereby reading out the internal frame data frm(2).

Hereinafter, similarly, (nₘₐₓ−2) pieces of internal frame data from frm(3) to frm(nₘₐₓ) are read out from the A₃ column in the order of the address number.

### 3.3. Timings for Error Correction (ECC Decoding)

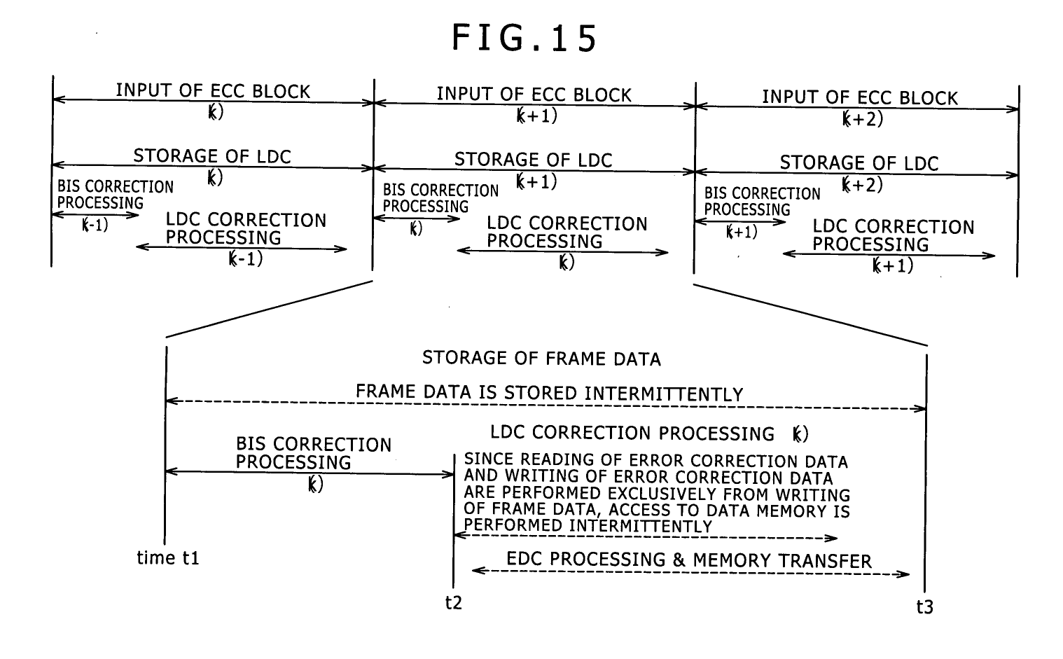

FIG. 15 is a timing chart of the error correction in the error correcting circuit 35 according to the another embodiment of the present invention. In FIG. 15, timings for the error correction in the k-th to (k+2)-th ECC block data are shown in a time series manner. The k-th LDC block data, and the k-th BIS block data are created from the k-th ECC block data.

In this case, the description will now be given by focusing on the (k+1)-th ECC block data inputted to the error correcting circuit 35. The (k+1)-th LDC block data obtained from the ECC block data is stored in the data memory 351 in order to correct the error(s) contained in the (k+1)-th LDC block data in the error correcting portion 357.

Now, as shown in FIG. 15, for a period of time (time t1 to t3) for which the (k+1)-th LDC block data is stored in the data memory 351, the LDC correction processing which is intended to be started to be executed at time t2 is executed so as to follow the BIS correcting processing which is started to be executed at time t1. In the BIS correction processing stated herein, the error(s) contained in the k-th BIS block data is (are) corrected. In addition, in the LDC correction processing, the error(s) contained in the k-th LDC block data is (are) corrected.

For a period of time (time from t1 to t2) for the BIS correction processing, the LDC correction processing cannot be executed concurrently with the BIS correction processing because the error correcting portion 357 is executing the BIS correction processing for the BIS block data. For this reason, although the k-th LDC block data the error(s) in which is (are) to be corrected is previously stored in the data memory 351, the k-th LDC block data the error(s) in which is (are) to be corrected cannot be outputted to the error correcting portion 357.

However, since the redundant storage area is provided in the data memory 351, even for a period of time for the BIS correction processing, the frame data composing the LDC block data, specifically, the internal frame data can be stored in the redundant storage area of the data memory 351. Of course, only the internal frame data having a data amount corresponding to a storage capacity of the redundant storage area is stored in the redundant storage area.

When the LDC correction processing is started to be executed at time t2 after completion of the BIS correction processing, the data memory 351 reads out the k-th LDC block data previously therein, specifically, the error correction data, and outputs the error correction data thus read out to the error correcting portion 357. Together with this reading operation, the data memory 351 stores the internal frame data which is inputted thereto one after another in the empty areas which occurs after completion of the operation for reading out the error correction data one after another. The error correction data the error(s) in which is (are) corrected is stored in the data memory 351, and is then outputted to the memory 4. On the other hand, after it is confirmed that the error correction data containing therein no error contains therein no error, the error correction data containing therein no error is outputted to the memory 4.

However, since the operation for reading out the error correction data from the data memory 351, and the operation for storing the internal frame data in the data memory 351 are carried out exclusively, the access to the data memory 351 is carried out intermittently.

For the operation for reading out the error correction data from the data memory 351, the operation for reading out the LDC block data (error correction data) previously stored in the data memory 351 needs to be completed until the (k+2)-th ECC block data is inputted to the error correcting circuit 35. In order to attain this, the amount of data which is to be read out from the data memory 351 has to be adjusted, and also a data bus width or operating frequency of the data memory 351 has to be adjusted.

### 3.4. Pointer Memory 354

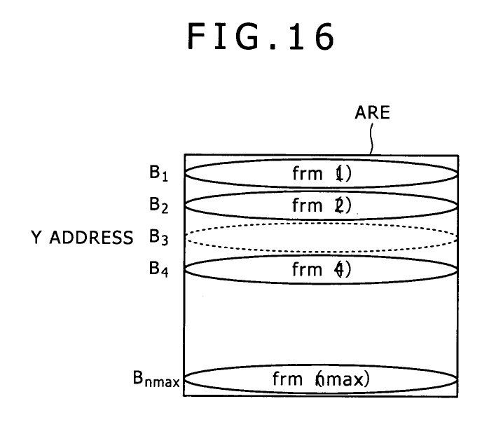

Now, a part of the data read out from the optical disc D may be corrupted by the burst error due to a damage, a fingerprint or the like on the surface of the optical disc D. In this case, a part of the internal frame data composing the LDC block data is lacked. Here, a method of storing the internal frame data in a general error correcting apparatus will be described below with reference to FIG. 16.

FIG. 16 is a schematic diagram showing a structure of a memory of the general error correcting apparatus. For example, one of two memories which the general error correcting apparatus has is shown in FIG. 16. This memory has a storage capacity allowing one piece of LDC block data to be stored therein. For example, it is assumed that nₘₐₓ pieces of internal frame data frm(1) to frm(nₘₐₓ) composing the LDC block data are stored in a row direction in this memory.

In general, firstly, the internal frame data frm(1) is stored in a B₁ row. Next, the internal frame data frm(2) is stored in a B₂ row. In this stage, for example, it is assumed that an error occurs in a phase of reading out data from the optical disc D, and thus the internal frame data frm(3) cannot be obtained.

Although under normal circumstances, the internal frame data frm(3) is stored in a B₃ row, since the internal frame data frm(3) is lacked, next internal frame data frm(4) is stored in a B₄ row. In FIG. 21, the internal frame data frm(3) thus lacked is indicated by a broken line. When one piece of internal frame data is lacked, (nₘₐₓ−1) pieces of internal frame data are stored in this memory.

In such a manner, the memory of the general error correcting apparatus can stores therein the internal frame data while it skips the address in which the lacked internal frame data is to be stored. In a phase as well of reading out the LDC block data, the memory of the general error correcting apparatus can read out the internal frame data in order while it skips an empty address number.

On the other hand, in the error correcting circuit 35 of the another embodiment, the data memory 351 stores therein the internal frame data and reads out therefrom the internal frame data while it makes the empty area. Here, it is assumed that as with the general error correcting apparatus, the data memory 351 stores therein the internal frame data while it skips the address in which the lacked internal frame data is to be stored. In this case, the empty area is insufficient, and thus it is difficult to properly carry out the first operation and the second operation which will be described later.

In order to cope with such a situation, the pointer memory 354, the second address circuit 353 and the fourth address circuit 356 are provided. Since the pointer memory 354 stores therein the pointers, as previously stated, it is possible to grasp which of the addresses what kind of frame data is stored in.

### In Phase of Storage

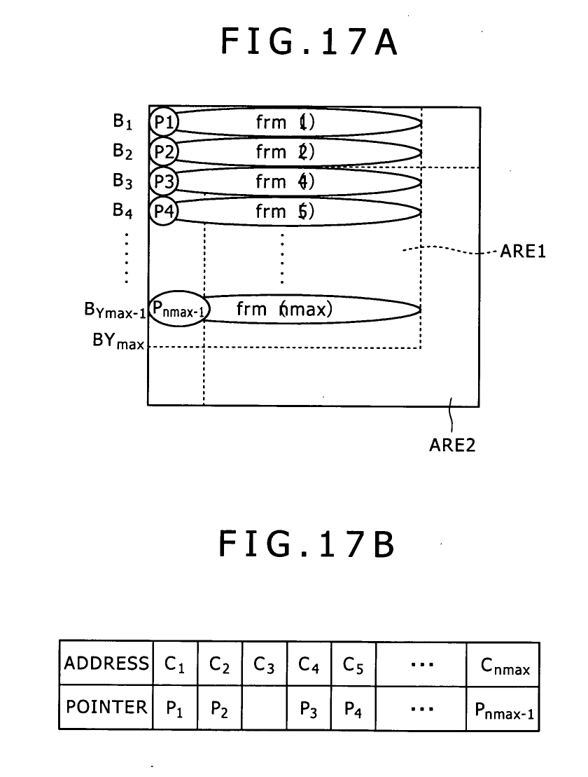

Hereinafter, an operation of the error correcting portion 357 when a part of the data is corrupted due to the burst error or the like will be described with reference to FIGS. 17A and 17B.

FIG. 17A is a schematic diagram showing a state of the data memory in the error correcting circuit according to the another embodiment of the present invention, and FIG. 17B is a schematic diagram showing a state of the pointer memory in the error correcting circuit according to the another embodiment of the present invention.

Firstly, the case where the LDC block data is stored in the data memory 351 will be described with reference to FIGS. 17A and 17B. In this description, it is assumed that although nₘₐₓ pieces of internal frame data frm(1) to frm(nₘₐₓ) composing the k-th LDC block data the error(s) in which is (are) to be corrected are stored in the row direction, only the internal frame data frm(3) is lacked.

When the data memory 351 stores the internal frame data frm(1) in the B₁ row, the pointer memory 354 shown in FIG. 17B stores the pointer P₁ indicating the place where the internal frame data frm(1) is stored in the address number C₁.

Also, when the data memory 351 stores the internal frame data frm(2) in the B₂ row, the pointer memory 354 stores the pointer P₂ indicating the place where the internal frame data frm(2) is stored in the address number C₂.

Although under normal circumstances, the data memory 351 stores the internal frame data frm(3) in the B₃ row, since the internal frame data frm(3) is lacked, the data memory 351 stores the next internal frame data frm(4) in the B₃ row. In other words, the data memory 351 stores therein the internal frame data without making the empty row.

At this time, since the frame number 3 is not outputted, even when the next frame number 4 is inputted, the second address circuit 353 does not specify the address number C₃ in the pointer memory 354, but specifies the address number C₄. Also, the first address circuit 352 stores the pointer P₃ indicating the place where the internal frame data frm(4) is stored in the address number C₄ in the pointer memory 354. For this reason, the address number C₃ becomes empty.

In such a manner, even a part of the internal frame data is lacked, the second address circuit 353 continues to increment the address number Cₙ.

Also, the data memory 351 stores the internal frame data frm(5) in the B₄ row. After that, when the data memory 351 stores the final internal frame data frm(nₘₐₓ) in the (B_{Ymax-1}) row, the pointer memory 354 stores the pointer Pₙₘₐₓ₋₁ indicating the place where the internal frame data frm(nₘₐₓ) is stored in the address number Cₙₘₐₓ.

### In Phase of Reading

Next, the case where the LDC block data is read out from the data memory 351 will be described with reference to FIGS. 17A and 17B. However, for the sake of simplicity of the description, it is assumed that the internal frame data is read out as the error correction data in the column direction.

When the pointer memory 354 reads out the pointer P₁ from the address number C₁, the data memory 351 reads out the error correction data ECC(1) from the B₁ row by referring to the pointer P₁.

Also, the pointer memory 354 reads out the pointer P₂ from the address number C₂, the data memory 351 reads out the error correction data ECC(2) from the B₂ row by referring to the pointer P₂.

Next, the pointer memory 354 reads out a pointer X from the address number C₃. Since no pointer is stored in the address number C₃, the pointer memory 354 reads out necessarily an indefinite value X as the pointer X. Then, the data memory 351 reads out the error correction data ECC(3) from an indefinite row by referring to the pointer X. Although the data read out from the indefinite row at this time is the incorrect data, the incorrect data is corrected in the phase of the error correction.

Next, the pointer memory 354 reads out the pointer P₃ from the next address number C₄. Then, the data memory 351 reads out the error correction data ECC(4) from the B₃ row by referring to the pointer P₃.

After that, when the pointer memory 354 reads out the pointer Pₙₘₐₓ₋₁ from the address number Cₙₘₐₓ, the data memory 351 reads out the error correction data ECC(nₘₐₓ₋₁) from the B_{Ymax} row by referring to the pointer Pₙₘₐₓ₋₁.

As set forth hereinabove, according to the error correction circuit 35 of the another embodiment, the data memory 351 has both the main storage area and the redundant storage area, and carries out the operation for storing the LDC block data, and the operation for reading out the LDC block data while it carries out alternately the first operation and the second operation.

Therefore, the error correction can be carried out by using a less number of memories than that of memories which the general error correcting apparatus uses, and thus a memory having a low memory capacity.

Although in the another embodiment, the error correction is carried out by using the data memory 351, the error correction may be carried out by using the memory 4 instead. In this case, all it takes is that the memory 4 having the same configuration as that of the data memory 351 is used.

### 4. Method of Controlling Data Memory 351

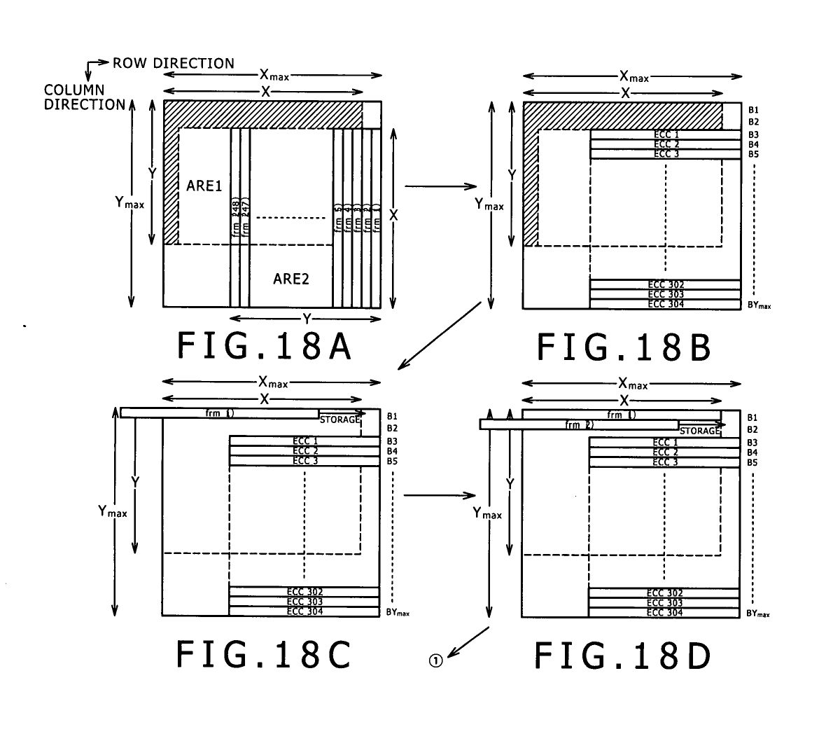

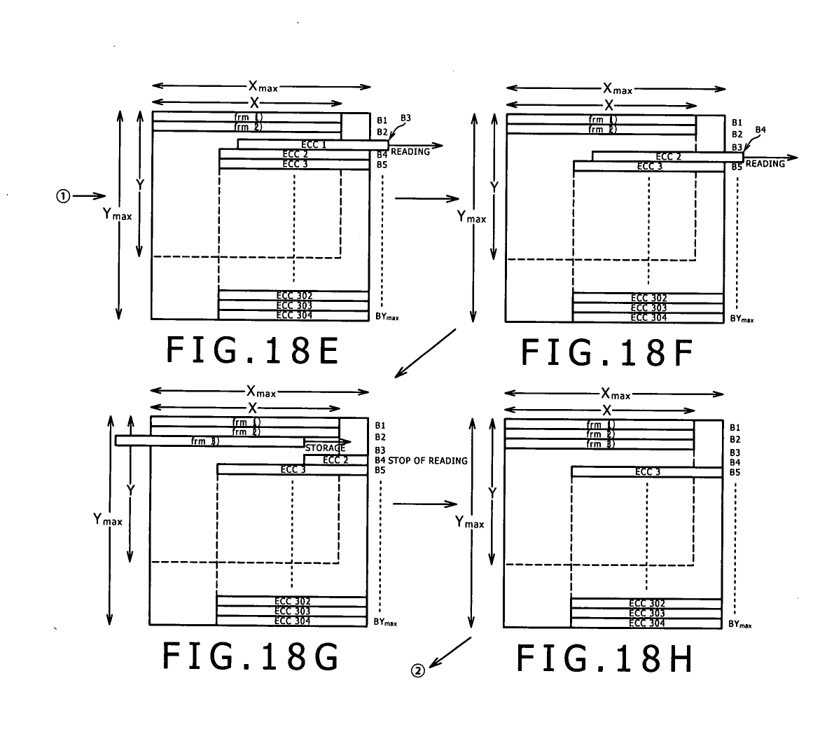

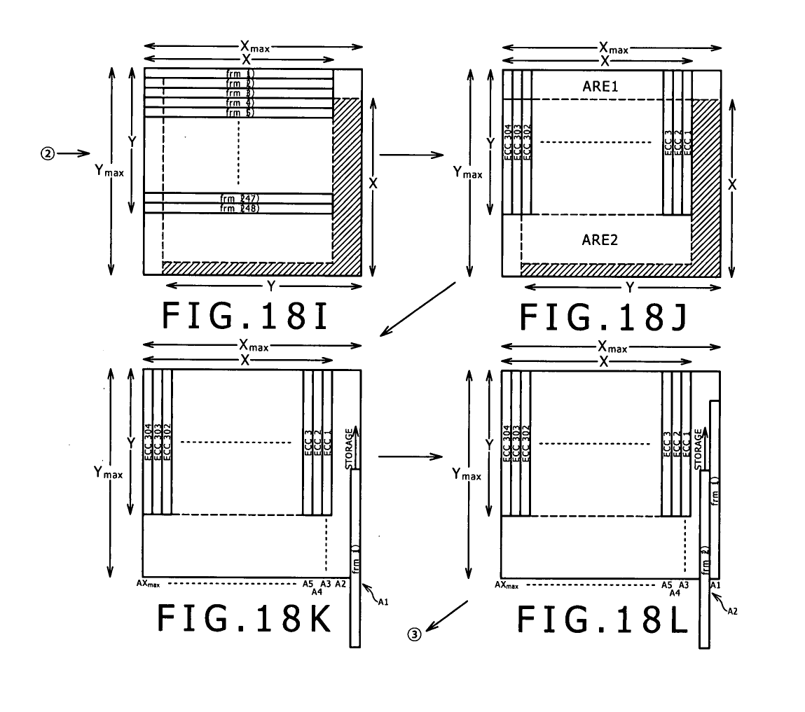

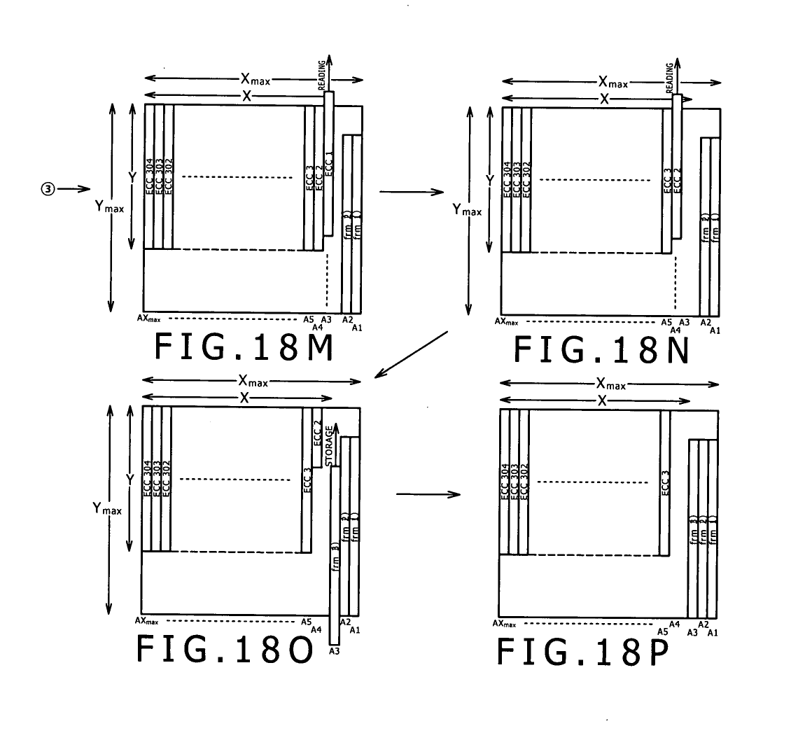

A method of controlling the data memory 351 will be described below based on the timing for the error correction shown in FIG. 15 with reference to FIGS. 18A to 18P.

FIGS. 18A to 18P are respectively schematic diagrams explaining a method of controlling the data memory according to still another embodiment of the present invention. It is noted that a portion indicated by slant lines in FIGS. 18A to 18P show the redundant storage area.

### 4.1 First Operation

For giving a description, an internal state shown in FIG. 18A is assumed. Specifically, it is assumed that the k-th LDC block data is stored in the second storage area ARE2. Under this assumption, the k-th LDC block data is the data before the error correction, and nₘₐₓ pieces of internal frame data from frm(1) to frm(nₘₐₓ (=248)) are stored in the second storage area ARE2 in the column direction (refer to FIG. 13A). Hereinbelow, for making the description clear up, it is assumed that the error correction data ECC(n) read out once is stored in the memory 4 because it contains therein no error. In addition, it is assumed that two pieces of internal frame data are stored in the redundant storage area.

After completion of the BIS correction processing for the (k−1)-th BIS block data, the LDC block data stored in the second storage area ARE2 is read out. However, in carrying out the error correction, the LDC data having the parity added thereto needs to be read out from the data memory 351 in the column direction. For this reason, as shown in FIG. 18B, the data stored in the second storage area ARE2 is treated as nₘₐₓ pieces of error correction data ECC(1) to ECC(nₘₐₓ (=304)) in the row direction.

Step ST1:

At a time point when the k-th LDC block data is stored in the second storage area ARE2, in other words, when 248 pieces of k-th internal frame data frm(1) to frm(nₘₐₓ (=248)) get together, the error correction for the BIS block data is started (at time t1; refer to FIG. 15). As previously stated, during the error correction for the (k−1)-th BIS block data, the error(s) contained in the (k−1)-th LDC block data cannot be corrected (refer to FIG. 15).

However, even for the period of time for the BIS correction processing, the internal frame data frm(1) composing the (k+1)-th LDC block data is inputted to the data memory 351. It is noted that the (k+1)-th LDC block data is also the data before the error correction. For this reason, the internal frame data frm(1) needs to be stored in the data memory 351.

Since a part of the first storage area ARE1, and a part of the second storage area ARE2 overlap each other, two pieces of LDC block data cannot be stored in the data memory 351 at the same time. However, since the empty redundant storage area exists in the data memory 351, a part of the internal frame data composing the (k+1)-th LDC block data can be stored in the redundant storage area. Specifically, since the empty area exists both in the B₁ row and the B₂ row in terms of the row direction, two pieces of internal frame data can be stored in the two rows, that is, in the B₁ row and in the B₂ row.

Then, as shown in FIG. 18C, the internal frame data frm(1) is stored in the B₁ row of the first storage area ARE1. At this time as well, it all takes is that the internal frame data frm(1) is stored in the B₁ row of the first storage area ARE1 similarly to the case of Step J11 previously described.

Step ST2:

After completion of the storage of the internal frame data frm(1), even during the error correction for the (k−1)-th BIS block data, the internal frame data frm(2) composing the (k+1)-th LDC block data is inputted to the data memory 351.

Since the empty area still exists in the redundant storage area, as shown in FIG. 18D, the internal frame data frm(2) is stored in the B₂ row of the first storage area ARE1.

Step ST3:

After completion of the BIS correction processing, while the new internal frame data frm is stopped to be inputted to the data memory 351, the k-th LDC block data stored in the second storage area ARE2 is started to be read out. Firstly, as shown in FIG. 18E, the error correction data ECC(1) in the head row of the second storage area ARE2, that is, in the B₃ row is read out. In this case, all it takes is that the error correction data ECC(1) is read out similarly to the case of Step R11 previously described.

Step ST4:

After completion of the operation for reading out the error correction data ECC(1), the k-th LDC block data is continuously read out until the internal frame data frm(3) composing the (k+1)-th LDC block data is inputted to the data memory 351. That is to say, as shown in FIG. 18F, the error correction data ECC(2) in the B₄ row is read out.

### Step ST5:

When during the operation for reading out the error correction data ECC(2), the internal frame data frm(3) composing the (k+1)-th LDC block data is inputted to the data memory 351, as shown in FIG. 18G, the operation for reading out the error correction data ECC(2) is temporarily stopped. Also, the internal frame data frm(3) is stored in the B₄ row. In such a manner, the storage of the internal frame data is prioritized.

Step ST6:

After completion of the operation for storing the internal frame data frm(3) in the data memory 351, the operation for reading out the error correction data ECC(2) is restarted. A state after completion of the reading-out operation is shown in FIG. 18H.

After that, the operation from Steps ST4 to ST6 is repetitively carried out, whereby the remaining (nₘₐₓ−2) pieces of error correction data from ECC(3) to ECC(nₘₐₓ (=304)) stored in the second storage area ARE2 are read out in order, and the remaining (nₘₐₓ−3) pieces of internal frame from frm(4) to frm(nₘₐₓ (=248)) are stored in the first storage area ARE1 in order. A state in this stage is shown in FIG. 18I.

From the above, describing the operation from Steps ST1 to ST6 in other words, the data memory 351 reads out nₘₐₓ pieces of error correction data ECC(1) to ECC (nₘₐₓ=304) which the k-th LDC block data the error(s) in which is (are) previously corrected and which is previously stored has in order in the row direction. The data memory 351 stores nₘₐₓ pieces of internal frame data frm(1) to frm(nₘₐₓ (=304)) which the (k+1)-th LDC block data has in the empty areas after completion of the reading-out operation in order in the row direction in conjunction with the reading-out operation described above. Here, the operation from Steps ST1 to ST6 is referred to as “the first operation.”

### 4.2. Second Operation

When the frame number, n, inputted to the error correcting circuit 35 is used, as shown in FIG. 18I, it is possible to know that the storage of the (k+1)-th LDC block data into the first storage area ARE1 is completed. That is to say, it is possible to grasp the completion of the first operation. After the error correcting circuit 35 grasps the completion of the first operation, the data memory 351 stores therein the new (k+2)-th LDC block data while it reads out the LDC block data.

Now, in order to correct the error(s) contained in the LDC block data in the first storage area ARE1, the data needs to be read out in a state in which the parity is added to the LDC data. Referring now to FIG. 18I, the parity corresponds to the internal frame data having low frame numbers from 217 to 248.

Then, when the LDC block data is read out, the data is read out in the form of nₘₐₓ pieces of error correction data ECC(1) to ECC(nₘₐₓ (=304)) in the column direction. For this reason, as shown in FIG. 18J, the frame numbers are allocated in the column direction.

Step ST7:

In a state shown in FIG. 18J, the empty area exists only in the redundant storage area of the second storage area ARE2. However, in this state, the internal frame data frm can be stored only in the empty area of the A₁ column and the A₂ column.

Then, as shown in FIG. 18K, the internal frame data frm(1) is stored in the A₁ column of the second storage area ARE2.

Step ST8:

After completion of the storage of the internal frame data frm(1) in the data memory 351, even during the error correction for the k-th BIS block data, the internal frame data frm(2) composing the (k+2)-th LDC block data is inputted to the data memory 351.

Since the empty area still exists in the redundant storage area, as shown in FIG. 18L, the initial frame data frm(2) is stored in the A₂ row of the second storage area ARE2.

Step ST9:

After completion of the BIS correction processing, while the new internal frame data frm is stopped to be inputted to the data memory 351, the (k+1)-th LDC block data stored in the second storage area ARE2 is started to be read out. Firstly, as shown in FIG. 18M, the error correction data ECC(1) in the head row of the first storage area, that is, in the A₃ row of the first storage area is read out.

Step ST10:

After completion of the operation for reading out the error correction data ECC(1), the (k+1)-th LDC block data is continuously read out until the internal frame data frm(3) composing the (k+2)-th LDC block data is inputted to the data memory 351. That is to say, as shown in FIG. 18N, the error correction data ECC(2) in the A₄ row is read out.

### Step ST11:

When the internal frame data frm(3) composing the (k+2)-th LDC block data is inputted to the data memory 351 during the operation for reading out the error correction data ECC(2), as shown in FIG. 18O, the operation for reading out the error correction data ECC(2) is temporarily stopped. Also, the internal frame data frm(3) is stored in the A₄ row. In this case as well, the storage of the internal frame data is prioritized.

### Step ST12:

After completion of the operation for storing the internal frame data frm(3) in the A₄ row, the operation for reading out the error correction data ECC(2) is restarted. A state after reading out operation is shown in FIG. 18P.

After that, the operation from Step ST10 to ST12 is repetitively carried out, whereby the remaining (nₘₐₓ−2) pieces of error correction data from ECC(3) to ECC(nₘₐₓ (=304)) stored in the first storage area ARE1 are read out and also the remaining (nₘₐₓ−3) pieces of internal frame data from frm(4) to frm(nₘₐₓ (=248)) are stored in the second storage area ARE2. A state in this stage is shown in FIG. 18P.

From the above, describing the operation from Steps ST7 to ST12 in other words, the data memory 351 reads out the nₘₐₓ pieces of internal frame data from frm(1) to frm(nₘₐₓ) which the (k+1)-th LDC block data has and which are stored in the first operation in order in the column direction. The data memory 351 stores the nₘₐₓ pieces of error correction data from ECC(1) to ECC(nₘₐₓ) which the (k+2)-th LDC block data has in the empty areas after completion of the reading-out operation in order in the column direction in conjunction with the reading-out operation described above. Here, the operation from Steps ST7 to ST12 is referred to as “the second operation.”

After this, the first operation and the second operation are alternately, repetitively carried out, whereby the data memory 351 carries out the storage and reading-out of the LDC block data.

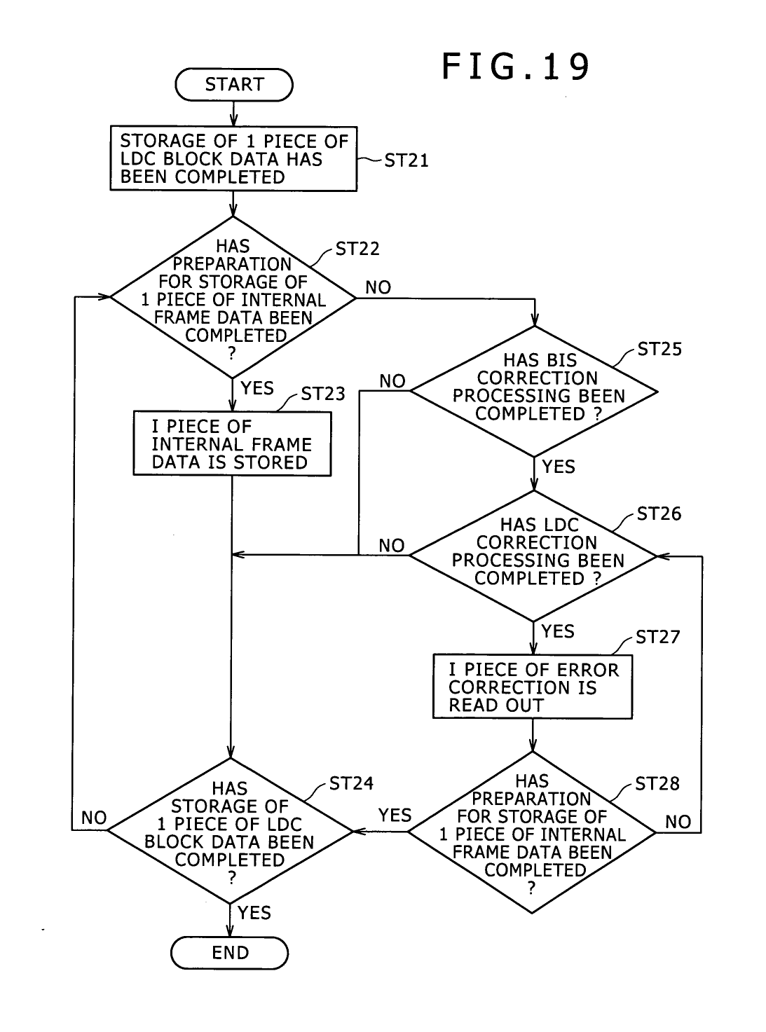

As has been described so far, the operation for storing the internal frame data in the data memory 351, and the operation for reading out the error correction data from the data memory 351 are carried out in the first operation and the second operation. Hereinafter, in what kind of case the internal frame data is stored, and in what kind of case the error correction data is read out will be described with reference to FIG. 19.

FIG. 19 is a flow chart explaining the operation for storing the internal frame data in the data memory, and the operation for reading out the error correction data from the data memory in the method of controlling the data memory according to the still another embodiment of the present invention. In this description, the first operation shown in FIGS. 18A to 18H is given as an example. Of course, the following operation also applies to the second operation. It is noted that for the sake of making the description easy, the place where the internal frame data is stored, and the error correction data to be read out are each arbitrary.

Step ST21:

It is assumed that firstly, the k-th LDC block data is stored in the second storage area ARE2 shown in FIG. 18B.

Step ST22:

It is determined whether or not the preparation for the storage of one piece of internal frame data composing the (k+1)-th LDC block data has been completed. The preparation for the storage stated herein means a state in which when the empty area in which the internal frame data is to be stored exists in the first storage area ARE1, the internal frame data can be stored in that empty area.

It is noted that this determination is carried out by the error correcting circuit 35. It is also noted that determinations in Step ST24, ST25, ST26, and ST28 which will be described below are also carried out by the error correcting circuit 35.

When it is determined in Step ST22 that the preparation for the storage of one piece of internal frame data composing the (k+1)-th LDC block data has been completed (YES), the operation proceeds to processing in Step ST23. On the other hand, when it is determined in Step ST22 that the preparation for the storage of one piece of internal frame data composing the (k+1)-th LDC block data has not yet been completed (NO), the operation proceeds to processing in Step ST25.

Step ST23:

When the preparation for the storage has been completed, one piece of internal frame data is stored either in the redundant storage area or in the empty area of the first storage area ARE1.

Step ST24:

It is determined whether or not the internal frame data for one piece of (k+1)-th LDC block data has been stored in the first storage area ARE1 through the storage of the internal frame data.

When it is determined in Step ST24 that 304 pieces of internal frame data have been stored in the first storage area ARE1 (YES), the first operation is completed. On the other hand, when it is determined in Step ST24 that 304 pieces of internal frame data have not yet been stored in the first storage area ARE1 (NO), the operation returns back to the processing in Step ST22.

Step ST25:

It is determined whether or not the BIS correction processing has been completed. When it is determined in Step ST25 that the BIS correction processing has been completed (YES), the operation proceeds to processing in Step ST26. On the other hand, when it is determined in Step ST25 that the BIS correction processing is continuously executed (NO), the operation proceeds to the processing in Step ST24.

Step ST26:

It is determined whether or not the LDC correction processing has been completed. When it is determined in Step ST26 that the LDC correction processing has been completed (YES), the operation proceeds to processing in Step ST27. On the other hand, when it is determined in Step ST26 that the LDC correction processing is continuously executed (NO), the operation proceeds to the processing in Step ST24.

Step ST27:

One piece of error correction data stored in the second storage area ARE2 is read out.

Step ST28:

The same processing as that in Step ST22 is executed.

Summarizing the series of processing described above, the internal frame data is successively stored in the empty area of the first storage area ARE1 as soon as the preparation for the storage of the internal frame data has already been completed.

When the preparation for the storage of the internal frame data has not yet been completed, after the LDC correction processing which is executed after completion of the BIS correction processing has been completed, the error correction data stored in the second storage area ARE2 is read out in order until the internal frame data for one piece of LDC block data is stored in the first storage area ARE1.

The present invention can be applied to not only the BD, but also a MD (Mini Disc: registered trademark), a Compact Disc (CD), or a Digital Versatile Disc (DVD).

The present application contains subject matter related to that disclosed in Japanese Priority Patent Application JP 2009-171467 filed in the Japan Patent Office on Jul. 22, 2009, the entire content of which is hereby incorporated by reference.

It should be understood by those skilled in the art that various modifications, combinations, sub-combinations and alterations may occur depending on design requirements and other factors insofar as they are within the scope of the appended claims or the equivalents thereof.

What is claimed is:

1. An error correcting apparatus, comprising:
a memory for storing therein second block data at an interval of a time difference while it uses at least a part of a storage area of first block data having multiple pieces of frame data each having data having a predetermined length as one unit; and
an error correcting portion configured to subject the first block data and the second block data each read out from said memory to error correction,
wherein said memory carries out alternately
a first operation for successively reading out the multiple pieces of frame data which the first block data stored has in a row direction, and successively storing the multiple pieces of frame data which the second block data has in an empty area obtained after the reading-out in the row direction in conjunction with the reading-out, and
a second operation for successively reading out the multiple pieces of frame data which the second block data has and which is stored in the first operation in a column direction, and successively storing the multiple pieces of frame data which the first block data has in an empty area obtained after the reading-out in the column direction in conjunction with the reading-out.

2. The error correcting apparatus according to claim 1, wherein said memory includes:
a main storage area in which either the first block data or the second block data is stored; and
a redundant storage area in which a predetermined number of pieces of frame data which the second block data has is stored when the first block data is stored in said main storage area, and a predetermined number of pieces of frame data which the first block data has is stored when the second block data is stored in said main storage area.

3. The error correcting apparatus according to claim 2, wherein
in the phase of the first operation, after said memory stores the predetermined number of pieces of frame data which the second block data has in said redundant storage area, said memory stores the remaining frame data which the second block data has in said main storage area, and
in the phase of the second operation, after said memory stores the predetermined number of pieces of frame data which the first block data has in said redundant storage area, said memory stores the remaining frame data which the first block data has in said main storage area.

4. The error correcting apparatus according to claim 3, further comprising:
a pointer holding portion configured to hold therein pointers indicating addresses for each frame data stored in said memory.

5. The error correcting apparatus according to claim 4, further comprising:
a pointer generating portion configured to generate the pointer whenever the frame data is stored in said memory,
wherein said pointer generating portion holds the pointer generated in order of the address in said pointer holding portion whenever said pointer generating portion generates the pointer.

6. The error correcting apparatus according to claim 5, further comprising:
an address specifying portion configured to specify the address in said pointer holding portion,
wherein even in a case where when said memory stores therein multiple pieces of frame data, the frame data is lacked, said address specifying portion continues to increment the address in said pointer holding portion.

7. The error correcting apparatus according to claim 5, further comprising:
a memory address specifying portion configured to acquire the pointer which said pointer holding portion holds therein, and specify the address in said memory in which the frame data to be read out is stored.

8. The error correcting apparatus according to claim 1, further comprising:
a memory address specifying portion configured to specify addresses in said memory in order of the address so that when said memory stores therein the multiple pieces of frame data, the multiple pieces of frame data are continuously stored either in the row direction or in the column direction of said memory.

9. A method of controlling a memory of an error correcting apparatus including a memory for storing therein second block data at an interval of a time difference while it uses a part of a storage area of first block data having multiple pieces of frame data each having data having a predetermined length as one unit, said error correcting apparatus serving to subject the first block data and the second block data each read out from said memory to error correction, said control method comprising the steps of:
successively reading out the multiple pieces of frame data which the first block data stored has in a row direction, and successively storing the multiple pieces of frame data which the second block data has in an empty area obtained after the reading-out in the row direction in conjunction with the reading-out; and
successively reading out the multiple pieces of frame data which the second block data has and which is stored in the first operation in a column direction, and successively storing the multiple pieces of frame data which the first block data has in an empty area obtained after the reading-out in the column direction in conjunction with the reading-out.

10. An optical disc recording/reproducing apparatus, comprising:
an optical pickup portion configured to record data in an optical disc by using a light having a previously prescribed wavelength, and read out the data from said optical disc;
an error correcting apparatus for subjecting said data which is to be recorded in said optical disc and the data which is read out from said optical disc by said optical pickup portion and which is to be reproduced to error correction;
a recording system for coding the data which is to be recorded and which is subjected to the error correction by said error correcting apparatus; and
a reproducing system for decoding the data which is to be reproduced before the error correction carried out by said error correcting apparatus;
said error correcting apparatus including
a memory for storing therein second block data at an interval of a time difference while it uses a part of a storage area of first block data having multiple pieces of frame data each having data having a predetermined length as one unit, and
an error correcting portion configured to subject the first block data and the second block data each read out from said memory to error correction,
wherein said memory carries out alternately
a first operation for successively reading out the multiple pieces of frame data which the first block data stored has in a row direction, and successively storing the multiple pieces of frame data which the second block data has in an empty area obtained after the reading-out in the row direction in conjunction with the reading-out, and
a second operation for successively reading out the multiple pieces of frame data which the second block data has and which is stored in the first operation in a column direction, and successively storing the multiple pieces of frame data which the first block data has in an empty area obtained after the reading-out in the column direction in conjunction with the reading-out.
